(19) United States
(12) Patent Application Publication
(10) Pub. No.: US 2026/0123226 A1
(43) Pub. Date: Apr. 30, 2026

(54) DISPLAY DEVICE

(71) Applicant: LG Display Co., Ltd., Seoul (KR)

(72) Inventors: Yang Sik LEE, Paju-si (KR); Joung Mi CHOI, Paju-si (KR); Su Chang AN, Paju-si (KR)

(73) Assignee: LG Display Co., Ltd., Seoul (KR)

(21) Appl. No.: 19/313,344

(22) Filed: Aug. 28, 2025

(30) Foreign Application Priority Data
Oct. 25, 2024 (KR) 10-2024-0147722

(51) Int. Cl. H10K 59/35; H10K 59/40; H10K 59/65; H10K 59/80; H10K 59/88

(52) U.S. Cl. CPC H10K 59/353; H10K 59/352; H10K 59/40; H10K 59/65; H10K 59/879; H10K 59/88

(57) ABSTRACT

A display device can include a display panel having a first display area, a second display area, and a boundary area arranged between the first display area and the second display area. The first display area, the second display area and the boundary area have different luminance from each other. The display device can further include a sensor corresponding to the second display area. The boundary area can include a light-emitting element and a lens part overlapping the light-emitting element.

### CROSS-REFERENCE TO RELATED APPLICATION

This application claims priority to and the benefit of Korean Patent Application No. 10-2024-0147722, filed in the Republic of Korea on Oct. 25, 2024, the disclosure of which is hereby expressly incorporated by reference in its entirety.

### BACKGROUND

### Field

The embodiment relate to a display device.

### Discussion of the Related Art

Multimedia capabilities of mobile terminals have been improved. For example, cameras are being built into smartphones by default, their resolution is increasing to the level of conventional digital cameras. A front camera of the smartphones restricts a screen design thereof, making it difficult to design the screen. Screen designs with notches or punch holes have been adopted in the smartphones to reduce the space taken up by the front camera, but the front camera and various sensors still limits the screen size, making it impossible to realize a full-screen display.

In order to implement a full-screen display, it is proposed to provide an imaging area with low-resolution pixels within a screen of a display panel, and to dispose electronic components such as a camera and various sensors in a position opposite to the imaging area below the display panel. Here, each of the pixels can include a plurality of sub-pixels.

However, in the case of a high-resolution display area in which high-resolution pixels are arranged and a low-resolution display area in which low-resolution pixels are arranged, there is a problem that a boundary between the high-resolution display area and the low-resolution display area is visible due to the luminance difference or the like between the high-resolution display area and the low-resolution display area. Since optical components can be arranged correspondingly in the low-resolution display area, the low-resolution display area can differ from the high-resolution display area in terms of the number of pixels per unit area (Pixels Per Inch (PPI)) or driving voltage, etc. As a result, the boundary between the high-resolution display area and the low-resolution display area can be visible, which can degrade the quality of the display device. The high-resolution display area can have a relatively higher luminance than the low-resolution display area, and thus can be a high-luminance display area. The low-resolution display area can be a low-luminance display area. Here, luminance can be referred to the intensity of light emitted in a particular direction. For example, gradation can mean intensity levels from the darkest to the brightest parts in an image, and can be represented in a range from 0 to 255. In the RGB color space, (R=255, G=255, B=255) can mean pure white, where the white can indicate the maximum luminance that the display device can represent.

And, in the case of a display device including the boundary between the high-luminance display area and the low-luminance display area, increasing voltages of some of the pixels arranged near the boundary to prevent, reduce, or minimize visibility of the boundary can result in increased voltage application to the pixels and thus deterioration of the pixels due to the increased voltage

Hence, there is a need for structurally improved display devices that prevent, reduce, or minimize visibility of the boundary between the high-resolution display area and the low-resolution display area.

### SUMMARY OF THE DISCLOSURE

Embodiments of the present disclosure provide a display panel and a display device including the same that improves luminance at a boundary between a high-luminance display area and a low-luminance display area.

Embodiments of the present disclosure provide a display panel and a display device including the same, wherein a lens is arranged near a boundary between the high-luminance display area and the low-luminance display area to prevent, reduce, or minimize visibility of the boundary due to the luminance difference between the high-resolution high-luminance display area and the low-luminance display area.

Objectives to be solved by embodiments are not limited to the objectives described above, and objectives which are not described above will be clearly understood by those skilled in the art from the following descriptions.

A display device according to embodiments of the present disclosure includes a display panel including a first display area, a second display area, and a boundary area arranged between the first display area and the second display area, the first display area, the second display area and the boundary area having different luminance from each other; and a sensor corresponding to the second display area, wherein the boundary area can include a light-emitting element and a lens part overlapping the light-emitting element.

A display device according to embodiments of the present disclosure includes a display panel including a first display area, a second display area, and a boundary area arranged between the first display area and the second display area, the first display area, the second display area and the boundary area having different luminance from each other, wherein the boundary area includes a lens part overlapping a light-emitting element, and wherein a luminance of a light emitted from the light-emitting element is adjusted by setting a size of the lens part relative to an emission area of the light-emitting element.

Embodiments of the present disclosure can use the lens part arranged within the display panel to prevent, reduce, or minimize visibility of the high-luminance display area and the low-luminance display area.

Embodiments of the present disclosure can use the lens part to prevent an increase in a voltage applied to the pixels and deterioration of the pixels due to the increase in voltage, thereby enabling low power operation and/or improved lifetime of the display device.

Embodiments of the present disclosure further include a dummy lens part in addition to the lens part, which allows for a more gradual change in luminance between the high-resolution display area and the low-resolution display area. Accordingly, visibility of the boundary between the high-resolution display area and the low-resolution display area can be further prevented, reduced, or minimized.

Various useful advantages and effects of the embodiments are not limited to the above-described contents, and effects which are not described above will be clearly understood by those skilled in the art from the following descriptions.

### BRIEF DESCRIPTION OF THE DRAWINGS

The above and other objects, features, and advantages of the present disclosure will become more apparent to those of ordinary skill in the art by describing example embodiments thereof in detail with reference to the attached drawings, in which:

FIG. 1 is a view illustrating a display panel and a display panel driver of a display device according to one or more embodiments of the present disclosure;

FIG. 2 is a view illustrating a first display area, a second display area, and a boundary area of the display panel according to one or more embodiments of the present disclosure;

FIG. 3 is a cross-sectional view schematically illustrating the display panel according to one or more embodiments of the present disclosure;

FIG. 4 is an enlarged view illustrating the first display area, the second display area, and the boundary area of the display panel according to one or more embodiments of the present disclosure;

FIG. 5 is a cross-sectional view illustrating a cross-sectional structure of a pixel area arranged in the first display area in the display panel according to one or more embodiments of the present disclosure;

FIG. 6 is a view illustrating a cross-sectional structure of a pixel area and a light transmitting area arranged in the second display area in the display device according to one or more embodiments of the present disclosure;

FIG. 7 is a view illustrating a cross-sectional structure of a pixel area arranged in the boundary area in the display device according to one or more embodiments of the present disclosure;

FIG. 8 is a view illustrating a portion of the display panel according to one or more embodiments arranged on the display device according to one or more embodiments of the present disclosure;

FIG. 9 is a view schematically illustrating a cross-section along line I-I′ of FIG. 8;

FIG. 10 is a view illustrating a portion of a display panel according to another embodiment arranged in the display device according to one or more embodiments of the present disclosure;

FIG. 11 is a view illustrating a portion of the display panel according to another embodiment arranged in the display device according to one or more embodiments of the present disclosure;
(a) of FIG. 12 is a view schematically illustrating a cross-section along line II-II′ of FIG. 11;
(b) of FIG. 12 is a view schematically illustrating a cross-section along line III-III′ of FIG. 11;
(c) of FIG. 12 is a view schematically illustrating a cross-section along line IV-IV′ of FIG. 11;

FIG. 13 is a view illustrating a portion of a display panel according to another embodiment arranged in the display device according to one or more embodiments of the present disclosure;

FIG. 14 is a view schematically illustrating a cross-section along line V-V′ of FIG. 13;

FIG. 15 is a view illustrating a portion of a display panel according to another embodiment arranged in the display device according to one or more embodiments of the present disclosure;
(a) of FIG. 16 is a view schematically illustrating a cross-section along line VI-VI′ of FIG. 15;
(b) of FIG. 16 is a view schematically illustrating a cross-section along line VII-VII′ of FIG. 15;

FIG. 17 is a view illustrating a portion of a display panel according to another embodiment arranged in the display device according to one or more embodiments of the present disclosure;

FIG. 18 is a view schematically illustrating a cross-section along line A-A′ of FIG. 17;

FIG. 19 is a view illustrating another embodiment of a dummy lens part arranged in the display device according to one or more embodiments of the present disclosure;

FIG. 20 is a view schematically illustrating a cross-section along line B-B′ of FIG. 19;

FIG. 21 is a view illustrating another embodiment of a dummy lens part arranged in the display device according to one or more embodiments of the present disclosure;

FIG. 22 is a view schematically illustrating a cross-section along line C-C′ of FIG. 21;

FIG. 23 is a view illustrating another embodiment of a dummy lens part arranged in a display device according to one or more embodiments of the present disclosure;

FIG. 24, including views (a) and (b), schematically illustrates a cross-section of a subdivided boundary area of FIG. 23;

FIG. 25 is a view illustrating another embodiment of a dummy lens part arranged in the display device according to one or more embodiments of the present disclosure; and

FIG. 26 is a view schematically illustrating a cross-section of a boundary area of FIG. 25, along line F-F′ of FIG. 25.

### DETAILED DESCRIPTION OF THE EMBODIMENTS

The advantages and features of the present disclosure and methods for accomplishing the same will be more clearly understood from embodiments described below with reference to the accompanying drawings. However, the present disclosure is not limited to the following embodiments but can be implemented in various different forms. Rather, the present embodiments will make the disclosure of the present disclosure complete and allow those skilled in the art to completely comprehend the scope of the present disclosure.

Shapes, sizes, ratios, angles, numbers, and the like disclosed in the drawings for describing the embodiments of the present disclosure are examples, and the present disclosure is not limited to the illustrated items. Like reference numerals refer to like elements throughout. In addition, in describing the present disclosure, if it is determined that the detailed description of the related known technology can unnecessarily obscure the subject matter of the present disclosure, the detailed description thereof will be omitted.

The terms such as “comprising”, “including”, “having” and “consisting of” used herein are generally intended to allow other components to be added unless the terms are used with the term “only”. References to the singular shall be construed to include the plural unless expressly stated otherwise. Further, the term “can” fully encompasses all the meanings and coverages of the term “may” and vice versa.

In interpreting a component, it is interpreted to include an error range even if there is no separate description.

In the case of a description of a positional relationship, for example, when the positional relationship of two parts is described as ‘on,’ ‘at an upper portion,’ ‘at a lower portion,’ ‘next to, and the like, one or more other parts can be located between the two parts unless ‘immediately’ or ‘directly’ is used.

In the description for the embodiments, the first, second, etc. are used to describe various components, but these components are not limited by these terms. These terms are only used to distinguish one component from another. Therefore, the first component mentioned below can be a second component within the technical spirit of the present disclosure.

Throughout the specification, the same reference numerals refer to the same component.

The features of each of the various embodiments can be combined or combined with each another, in whole or in part, and various technical interlocking and driving can be possible, and each of the embodiments can be implemented independently of each other or in conjunction with each other.

Recently, the importance of a display device as a visual information transmission medium has been further emphasized in information-oriented society, and display devices are being improved to meet requirements, such as low power consumption, reduction of thickness, weight reduction, high definition, high efficiency, and the like.

A display device according to one or more embodiments of the present disclosure can use a lens arranged within a display panel to change an optical path of light emitted from a light-emitting element, thereby preventing, reducing, or minimizing visibility of a boundary between a high-resolution display area and a low-resolution display area. Here, the high-resolution display area can be a first display area, and the low-resolution display area in which an optical member is correspondingly arranged can be a second display area.

The display device according to one or more embodiments of the present disclosure can improve the display quality of the display device by presenting various embodiments of a lens arranged at a boundary or a boundary area of the high-resolution display area and the low-resolution display area.

A display device according to various embodiments of the present disclosure will now be described referring to the drawings. All the components of each display device/apparatus according to all embodiments of the present disclosure are operatively coupled and configured.

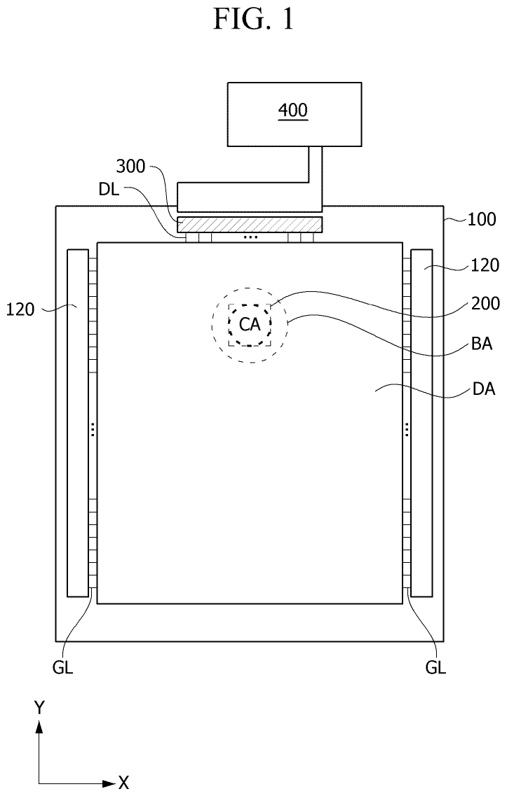

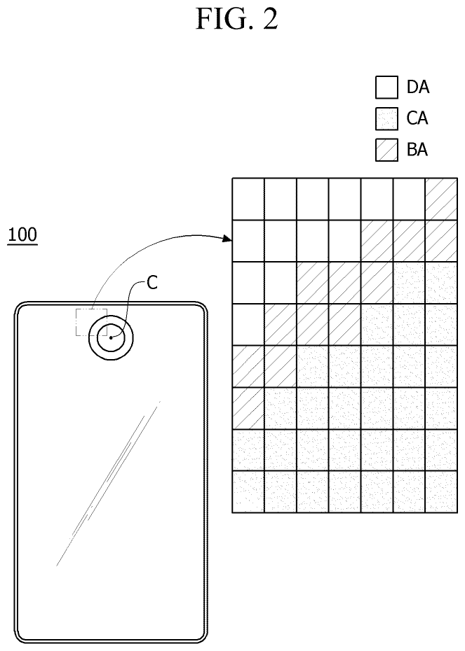

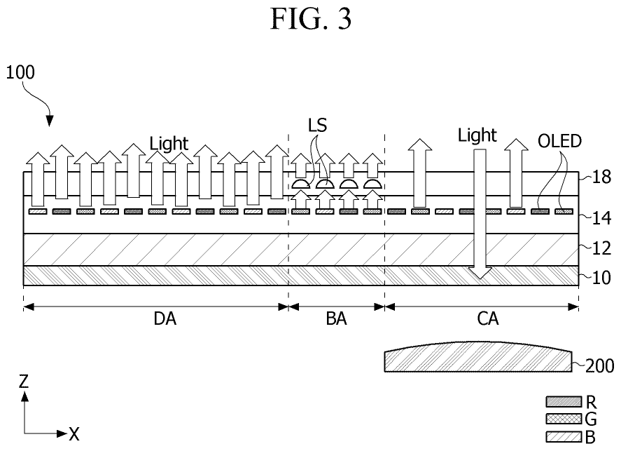

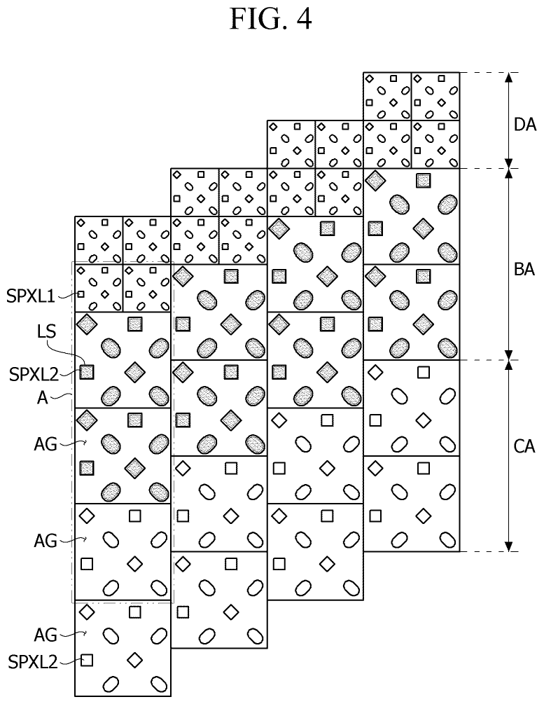

FIG. 1 is a view illustrating a display panel and a display panel driver of a display device according to one or more embodiments of the present disclosure. FIG. 2 is a view illustrating a first display area, a second display area, and a boundary area of the display panel according to one or more embodiments of the present disclosure. FIG. 3 is a cross-sectional view schematically illustrating the display panel according to the embodiment of the present disclosure. FIG. 4 is an enlarged view illustrating the first display area, the second display area, and the boundary area of the display panel according to one or more embodiments of the present disclosure. For example, FIG. 4 is a view that further enlarges the enlarged area of FIG. 2. Further, the boundary area illustrated in FIG. 4 can be a boundary area according to the first embodiment, and the display panel including the boundary area according to the first embodiment can be a display panel according to the first embodiment.

Referring to FIGS. 1 to 4, the display device according to one or more embodiments of the present disclosure can include a display panel 100 and an optical device 200. The display device can further include a case that protects the display panel 100 and the optical device 200.

The display panel 100 can implement a screen of a full-screen display. The optical device 200 can include an image sensor (or camera), a proximity sensor, a white light illumination element, an optical element for facial recognition, and the like. For example, the optical device 200 can include at least one of an image sensor, a proximity sensor, an illuminance sensor, a gesture sensor, a motion sensor, a fingerprint recognition sensor, and a biometric sensor.

The display area of the display panel 100 can include a first display area DA, a second display area CA in which the optical device 200 is correspondingly arranged, and a boundary area BA between the first display area DA and the second display area CA.

The first display area DA, the second display area CA, and the boundary area BA between the first display area DA and the second display area CA can all output images. In this case, the first display area DA and the second display area CA can have different luminance. Further, the luminance of the boundary area BA can be different from the luminance of the first display area DA and the luminance of the second display area CA. For example, the luminance of the boundary area BA can be higher than the luminance of the second display area CA, and the luminance of the boundary area BA can be lower than the luminance of the first display area DA. Here, luminance can refer to the intensity of light emitted in a particular direction. Further, gradation can mean intensity levels from the darkest to the brightest parts in an image, and can be represented in a range from 0 to 255 in 8-bit data. For example, in a RGB color space, a pixel data (R=255, G=255, B=255) is a gradation value that implements the luminance of peak white. The peak white can be the maximum luminance that the display device can represent. In a display device, when a same gradation value, for example, a peak white gradation value of ‘255’ is written in pixels in the first display area DA, the second display area CA, and the boundary area BA, the first display area DA, the second display area CA, and the boundary area BA can have different luminance values.

Hence, in the display device according to the embodiment of the present disclosure, even though the luminance difference occurs between the first display area DA and the second display area CA, the boundary area BA, which has the luminance value within a range between the luminance value of the first display area DA and the luminance value of the second display area CA, can be used to prevent, reduce, or minimize visibility of the boundary caused by the luminance difference between the first display area DA and the second display area CA. For example, the display device according to the embodiment of the present disclosure causes a blur effect, which provides a gradation in luminance between the first display area DA and the second display area CA through use of the boundary area BA, thereby preventing, reducing, or minimizing visibility of the boundary due to the luminance difference between the first display area DA and the second display area CA.

In addition, the first display area DA and the second display area CA can have different resolutions. For example, a resolution of a plurality of pixels arranged in the second display area CA can be lower than a resolution of a plurality of pixels arranged in the first display area DA. The lower the resolution of the plurality of pixels arranged in the second display area CA, the more sufficient light can be introduced into the optical device 200 arranged in the second display area CA.

The second display area CA can be an area in which the optical device 200 is arranged. The second display area CA can be an area that overlaps with various sensors, and therefore can be relatively smaller in area than the first display area DA that outputs most of the image.

The second display area CA can be arranged at various locations where light incidence is required. For example, the second display area CA can be arranged at the top center of the display area, as shown in FIG. 2, but is not necessarily limited thereto. The second display area CA can be arranged at the top left or right of the display area. Alternatively, the second display area CA can be arranged entirely over the top of the display area. Alternatively, the second display area CA can be arranged at the center of the display area or at the bottom of the display area. Here, the first display area DA can be a display area, the second display area CA can be an imaging area or a hole area, and the boundary area BA can be a blur area or a gradient area.

The first display area DA and the second display area CA can include a pixel array arranged with pixels in which pixel data is written. To ensure light transmittance of the second display area CA, the number of pixels per unit area (Pixels Per Inch (PPI)) of the second display area CA can be lower than the number of pixels per unit area (Pixels Per Inch) of the first display area DA.

The pixel array of the first display area DA can include a pixel area in which a plurality of pixels having a high number of pixels per unit areas (Pixels Per Inch) are arranged. The pixel array of the second display area CA can include a pixel area in which a plurality of pixels having a relatively low number of pixels per unit areas (Pixels Per Inch) spaced apart by a light transmitting area are arranged. In the second display area CA, external light can penetrate the display panel 100 through the light transmitting area having a high light transmittance and thus can be received by an optical device (or sensor) under the display panel 100.

A plurality of pixels can also be arranged in the boundary area BA. The pixel can include a plurality of sub-pixels including light-emitting elements. For example, the boundary area BA can have light-emitting elements of the sub-pixels arranged to overlap the lens part LS. Here, the pixels arranged in the boundary area BA can be the same pixels as the pixels in the first display area DA and/or the pixels in the second display area CA. For example, in the display panel 100, the boundary area BA can be formed by arranging the lens part LS to overlap sub-pixels of the second display area CA that are arranged adjacent to the pixels of the first display area DA. Alternatively, in the display panel 100, the boundary area BA can be formed by arranging the lens part LS to overlap sub-pixels of the first display area DA that are arranged adjacent to the pixels of the second display area CA. Alternatively, in the display panel 100, the boundary area BA can be formed by arranging the lens part LS to overlap both sub-pixels of the first display area DA and sub-pixels of the second display area CA that are arranged near the boundary between the first display area DA and the second display area CA.

Since the first display area DA, the second display area CA, and the boundary area BA all include pixels, the input image can be reproduced on the first display area DA, the second display area CA, and the boundary area BA.

Each of the pixels in the first display area DA, the second display area CA, and the boundary area BA can include different colored sub-pixels to implement the color of the image. The sub-pixels can include a red sub-pixel, a green sub-pixel, and a blue sub-pixel. Each of the pixels can further include a white sub-pixel. Further, each of the sub-pixels can include a pixel circuit and a light-emitting element. Here, the sub-pixel arranged in the first display area DA can be a first sub-pixel PXL1, and the sub-pixel arranged in the second display area CA can be a second sub-pixel SPXL2. Further, the light-emitting element can be implemented in a device structure such as an organic light emitting diode (OLED) display, a quantum dot display, a micro light emitting diode (Micro LED) display, and the like. Hereinafter, an OLED structure including an organic compound layer will be described as an example.

The second display area CA can include pixels, and the pixels can be written with pixel data of the input image to display the input image during a display mode. In this case, since the optical devices 200 are arranged below the back surface of the display panel 100 to overlap the second display area CA, the display area of the screen is not restricted by the optical devices 200. Accordingly, the display device according to an embodiment of the present disclosure can enlarge the display area of the screen to implement a screen of a full-screen display and increase the freedom of screen design.

The optical device 200 can provide a camera module, and the camera module can capture an external image during an imaging mode to output photo or video image data. In this case, lens of the camera module can face the second display area CA. Further, external lights can be incident on the lens of the camera module through the second display area CA, and the lens of the camera module can focus the lights on the image sensor. Accordingly, the camera module can capture the external images in the imaging mode and output photo or video image data.

Further, the camera module provided by the optical device 200 can be an infrared camera including an infrared sensor. An infrared camera captures dot beams of infrared wavelengths on a person's face. The infrared camera can convert light of an infrared wavelength that has passed through the display panel 100 into an electrical signal and convert it into digital data to generate facial pattern data. Thus, when the infrared light irradiated by the infrared illumination element is irradiated on the user's face, and the infrared light reflected from the face is received by the infrared camera, the biometric authentication module of the host system processes the user authentication. The infrared illumination element can utilize Flood illuminator that generates infrared (IR) flashes, thereby enabling facial recognition even in a dark environment.

On the other hand, some pixels can be removed from the second display area CA to ensure light transmittance in the second display area CA. In this case, a picture quality compensation algorithm can be adopted for the display device to compensate for the luminance and color coordinates of the pixels arranged in the second display area CA that are affected by the removal of pixels, but is not necessarily limited thereto.

In the present disclosure, low-resolution pixels can be disposed in the second display area CA. Therefore, since the display area of the screen is not limited due to the camera module, a full-screen display can be implemented.

The display panel 100 can have a width in the X-axis direction, a length in the Y-axis direction, and a thickness in the Z-axis direction. Here, the width and length of the display panel 100 can be set to various design values depending on application fields of the display device. In addition, the X-axis direction can mean a width direction or a horizontal direction, the Y-axis direction can mean a longitudinal direction or a vertical direction, and the Z-axis direction can mean a vertical direction, a stacking direction, or a thickness direction. Here, the X-axis direction, the Y-axis direction, and the Z-axis direction can be perpendicular to each other, but can also mean different directions that are not perpendicular to each other. Each of the X-axis direction, the Y-axis direction, and the Z-axis direction can be described as one of a first direction, a second direction, or a third direction. Further, the plane extended in the X-axis direction and the Y-axis direction can mean a horizontal plane.

The display panel 100 can include a circuit layer 12 disposed on the substrate 10 and a light-emitting element layer 14 disposed on the circuit layer 12. In addition, the display panel 100 can include a encapsulation layer 16 disposed on the light-emitting element layer 14 and a touch sensor layer 18 disposed on the encapsulation layer 16.

The substrate 10 can be formed of an insulating material or a material having flexibility. For example, the substrate 10 can be made of glass, metal, or plastic, but is not limited thereto.

The circuit layer 12 can include a pixel circuit connected to wirings such as data lines, gate lines, and power lines, a gate driver connected to the gate lines, and the like. Further, the circuit layer 12 can include transistors implemented with thin film transistors (TFTs) and circuit elements such as capacitors or the like. Here, the wirings and circuit elements of the circuit layer 12 can be implemented with a plurality of insulating layers, two or more metal layers separated with the insulating layer interposed therebetween, and an active layer including a semiconductor material.

The light-emitting element layer 14 can include a light emitting element driven by a pixel circuit. Here, the light emitting element can be implemented with an organic light emitting diode (OLED). The OLED can include an organic compound layer formed between an anode and a cathode. The organic compound layer includes a hole injection layer (HIL), a hole transport layer (HTL), an emission layer (EML), an electron transport layer (ETL), and an electron injection layer (EIL), but is not limited thereto. When a voltage is applied to an anode and an cathode of the OLED, the holes passing through the hole transport layer (HTL) and the electrons passing through the electron transport layer (ETL) can be moved to the light emitting layer (EML) to form excitons and emit visible light from the light emitting layer (EML).

The light-emitting element layer 14 can further include a color filter array disposed on the pixels to selectively transmit red, green, and blue wavelengths.

The light-emitting element layer 14 can be covered by a protective film, and the protective film can be covered by an encapsulation layer. Here, the protective film can have a structure in which organic films and inorganic films are alternately stacked. In this case, the inorganic film can block penetration of moisture or oxygen. In addition, the organic film can planarize the surface of the inorganic film. When the organic film and the inorganic film are stacked in multiple layers, a movement path of moisture or oxygen is longer than that of a single layer, so that the penetration of moisture/oxygen affecting the light-emitting element layer 14 can be effectively blocked.

The encapsulation layer 16 covers the light-emitting element layer 14 so as to seal the circuit layer 12 and the light-emitting element layer 14. Here, the encapsulation layer 16 can have a multi-insulation film structure in which the organic film and the inorganic film are alternately stacked. In this case, the inorganic film blocks penetration of moisture or oxygen. In addition, the organic film planarizes the surface of the inorganic film. When the organic film and the inorganic film are stacked in multiple layers, the movement path of moisture or oxygen is longer than that of a single layer, so that the penetration of moisture/oxygen affecting the light-emitting element layer 14 can be effectively blocked.

The touch sensor layer 18 can include capacitive touch sensors that sense a touch input based on a change in capacitance before and after the touch input. The touch sensor layer 18 can include metal wiring patterns and insulating films forming capacitance of the touch sensors. The insulating films can insulate portions in which the metal wiring patterns are intersected and planarize the surface of the touch sensor layer.

A polarizing plate omitted in the drawing can be adhered on the touch sensor layer 18. The polarizing plate can improve visibility and contrast ratio by converting polarization of external light reflected by the metal patterns of the circuit layer 12. Further, a cover glass omitted from the drawings can be adhered on the polarizing plate.

The color filter layer can be formed on the touch sensor layer 18. The color filter layer can include red, green, and blue color filters. In addition, the color filter layer can further include a black matrix pattern. The color filter layer 20 can absorb some wavelengths of light reflected from the circuit layer 12 to replace the role of a polarizing plate and increase color purity. A cover glass omitted in the drawings can be adhered on the color filter layer.

The color filter layer can include an organic film covering the color filter and the black matrix pattern. An extended portion of the organic film can cover the remaining inorganic film or the substrate 10 in the bezel area, that is, the edge area of the display panel 100.

Referring to FIG. 4, the first display area DA can include pixels arranged in a matrix, and each of the pixels can include a plurality of sub-pixels. For example, the first display area DA can include a plurality of first sub-pixels SPXL1, and the first sub-pixels SPXL1 can include a pixel circuit and a light-emitting element. Here, the light-emitting element of the first sub-pixel SPXL1 can be a first light-emitting element.

The second display area CA can include pixels arranged in a matrix, and each of the pixels can include a plurality of sub-pixels. For example, the second display area CA can include a plurality of second sub-pixels SPXL2, and the second sub-pixels SPXL2 can include a pixel circuit and a light-emitting element. Here, the light-emitting element of the second sub-pixel SPXL2 can be a second light-emitting element.

The first display area DA and the second display area CA can differ in number of pixels per unit area (Pixels Per Inch (PPI)). For example, the number of first sub-pixels SPXL1 per unit area in the first display area DA and the number of second sub-pixels SPXL2 per unit area in the second display area CA can be different. Further, the first sub-pixel SPXL1 and the second sub-pixel SPXL2 can differ in size, spacing distance, etc. For example, the size of the second sub-pixel SPXL2 can be larger than the size of the first sub-pixel SPXL1, but is not necessarily limited thereto. Further, a spacing between a plurality of second sub-pixels SPXL2 can be larger than a spacing between a plurality of first sub-pixels SPXL1, but is not necessarily limited thereto.

Since the second display area CA can have a relatively smaller number of pixels per unit area (Pixels Per Inch (PPI)) than the first display area DA, a light transmitting area AG can be arranged between the plurality of second sub-pixels SPXL2, but is not necessarily limited thereto. For example, the light transmitting area AG can be arranged between a plurality of pixels including the plurality of second sub-pixels SPXL2. This allows a sufficient amount of light to be introduced into the optical device 200 through the light transmission area AG.

The plurality of light transmitting areas AG can be arranged between a plurality of second sub-pixels SPXL2. Specifically, the second display area CA can include the light transmitting areas AG arranged between two neighboring second sub-pixels SPXL2 spaced apart by a predetermined distance. Through the light transmitting area AG, external lights can be received by the lens of the camera module.

The light transmitting area AG can include transparent medium having high light transmittance without metal to allow light pass through with minimal light loss. The light transmitting area AG can be made of a transparent insulating material that does not including any metal wire or pixels (or sub-pixels). Accordingly, the light transmittance of the second display area CA can be higher as the light transmitting area AG is larger.

The shape of the light transmitting area AG is illustrated as a rectangle, but is not limited to thereto. For example, the light transmitting area AG can be designed in various shapes such as circular, elliptical, polygonal, etc.

The display device according to embodiment of the present disclosure can include the display panel 100 having a pixel array arranged on a screen, the display panel driver, etc.

The pixel array of the display panel 100 can include data lines DL, gate lines GL intersecting the data lines DL, and pixels connected to the data lines DL and gate lines GL and arranged in a matrix.

The pixel array can be divided into a circuit layer 12 and a light-emitting element layer 14, as shown in FIG. 3. Then, a touch sensor array can be arranged on the light-emitting element layer 14. Here, each of the pixels of the pixel array can include two to four sub-pixels. Each of the sub-pixels can include a pixel circuit arranged in the circuit layer 12.

Each of the sub-pixels of the first display area DA, the second display area CA, and the boundary area BA can include a pixel circuit. The pixel circuit can include a driving element to supply current to the light-emitting element (OLED), a plurality of switching elements to sample a threshold voltage of the driving element and switch a current path of the pixel circuit, a capacitor to maintain a gate voltage of the driving element, etc. In this case, the pixel circuit can be arranged below the light-emitting element.

The display panel driver can write pixel data of an input image into the pixels. The pixels can be interpreted as a pixel group including a plurality of sub-pixels.

The display panel driver can include a data driver that supplies a data voltage of pixel data to the data lines DL and a gate driver 120 that sequentially supplies gate pulses to the gate lines GL. Further, the data driver can be integrated into the drive IC 300. In addition, the display panel driver can further include a touch sensor driver omitted from the drawings.

The drive IC 300 can be bonded on the display panel 100. The drive IC 300 receives pixel data of an input image and a timing signal from the host system 200, supplies a data voltage of the pixel data to pixels, and synchronizes the data driver and the gate driver 120.

The drive IC 300 can be connected to the data lines DL through data output channels to supply data voltages of pixel data to the data lines DL. The drive IC 300 can output a gate timing signal for controlling the gate driver 120 through gate timing signal output channels.

The gate driver 120 can include a shift register formed on a circuit layer of the display panel 100 together with a pixel array. The shift register of the gate driver 120 can sequentially supply gate signals to the gate lines GL under the control of the timing controller. The gate signal can include a scan pulse and an EM pulse of an emission signal.

The host system 400 can be implemented with an application processor (AP). The host system 400 can transmit pixel data of an input image to the drive IC 300 through a mobile industry processor interface (MIPI). The host system 400 can be connected to the drive IC 300 through a flexible printed circuit, for example, a flexible printed circuit (FPC).

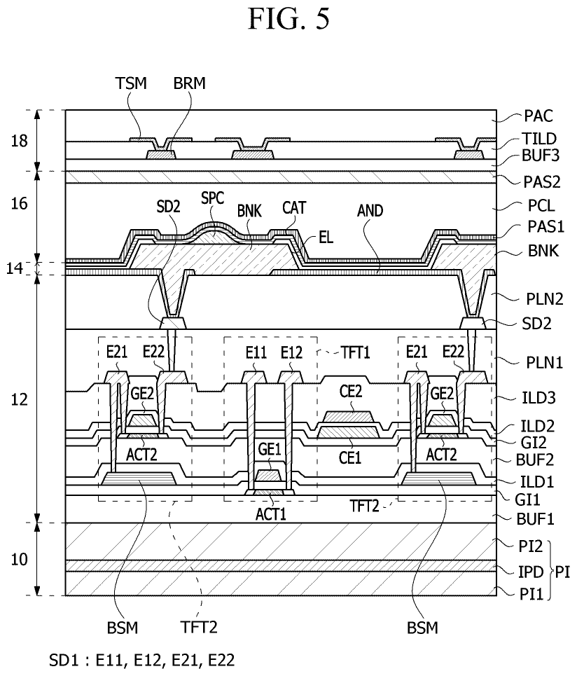

FIG. 5 is a cross-sectional view of a cross-sectional structure of a pixel area disposed in a first display area in a display panel according to one or more embodiments of the present invention. Here, it should be noted that the cross-sectional structure of the pixel area is not limited to that of FIG. 5. In FIG. 5, TFT represents a driving element of the pixel circuit. In detail, TFT1 is a first TFT that is one of LTPS TFTs disposed in the display area, and TFT2 is a second TFT that is one of oxide TFTs disposed in the display area.

Referring to FIG. 5, a plurality of pixel circuits and wires connected to the pixel circuits can be disposed in the display area DA of the display panel 100. Here, the pixel circuits of the display area can include a pixel circuit of a red sub-pixel driving a red light emitting element, a pixel circuit of a green sub-pixel driving a green light emitting element, and a pixel circuit of a blue sub-pixel driving a blue light emitting element. Further, the display area can be separated into a plurality of circuit areas along the X-axis direction of the display panel 100.

The substrate PI can include first and second substrates PI1 and PI2. In addition, an inorganic film IPD can be formed between the first substrate PI1 and the second substrate PI2. In this case the inorganic film IPD can block moisture permeation. Here, since the substrate PI can be formed of polyimide, it can be referred to as a PI substrate, and the first and second substrates PI1 and PI2 can be referred to as first and second PI substrates.

The first buffer layer BUF1 can be formed on the second substrate PI2. The first buffer layer BUF1 can be formed of a multi-layered insulating layer in which two or more oxide layers SiO₂ and nitride layers SiNx are stacked. A first semiconductor layer is formed on the first buffer layer BUF1. The first semiconductor layer can include a polysilicon semiconductor layer patterned in a photolithography process. The first semiconductor layer can include a polysilicon active pattern ACT1 forming a semiconductor channel in the first TFT TFT1.

A first gate insulating layer GI1 is deposited on the first buffer layer BUF1 to cover the active pattern ACT1 of the first semiconductor layer. The first gate insulating layer GI1 includes an inorganic insulating material layer. A first metal layer is formed on the first gate insulating layer GI1. The first metal layer is insulated from the first semiconductor layer by the first gate insulating layer GI1.

The first metal layer can include a single metal layer patterned in a photolithography process or metal patterns in which two or more metal layers are stacked. The first metal layer can include the gate electrode GE1 of the first TFT TFT1 and a light shield pattern BSM under the second TFT TFT 2.

A first interlayer insulating layer ILD1 is formed on the first gate insulating layer GI1 to cover the patterns of the first metal layer. The first interlayer insulating layer ILD1 can include an inorganic insulating material. A second buffer layer BUF2 is formed on the first interlayer insulating layer ILD1. The second buffer layer BUF2 can include a single layer or a multi-layer inorganic insulating material.

The second semiconductor layer can include an oxide semiconductor pattern ACT2 forming a semiconductor channel in the second TFT TFT2. The second gate insulating layer GI2 can be deposited on the second buffer layer BUF2 to cover the active pattern ACT2 of the second semiconductor layer. The second gate insulating layer GI2 can include a single or multi-layered inorganic insulating material. A second metal layer can be formed on the second gate insulating layer GI2. The second metal layer can be insulated from the second semiconductor layer by the second gate insulating layer GI2.

The second metal layer can include a single metal layer patterned in a photolithography process or metal patterns in which two or more metal layers are stacked. The second metal layer can include a gate electrode GE2 of the second TFT TFT2 and a lower capacitor electrode CE1.

A second interlayer insulating layer ILD2 can be formed on the second gate insulating layer GI2 to cover the patterns of the second metal layer. The second interlayer insulating layer ILD2 can include a single layer or a multi-layer inorganic insulating material. A third metal layer can be formed on the second interlayer insulating layer ILD2. The third metal layer can be insulated from the second metal layer by the second interlayer insulating layer ILD2.

The third metal layer can include a single metal layer patterned in a photolithography process or metal patterns in which two or more metal layers are stacked. The third metal layer can include an upper capacitor electrode CE2. The capacitor Cst of the pixel circuit can be composed of the upper capacitor electrode CE2, the lower capacitor electrode CE1, and a dielectric layer therebetween, that is, the second interlayer insulating layer ILD2.

A third interlayer insulating layer ILD3 covering the patterns of the third metal layer can be formed on the second interlayer insulating layer ILD2. The third interlayer insulating layer ILD3 can include a single layer or a multi-layer inorganic insulating material. A fourth metal layer can be formed on the third interlayer insulating layer ILD3. The fourth metal layer can be insulated from the second semiconductor layer by the second gate insulating layer GI2.

A fourth metal layer SD1 can include a single metal layer patterned in a photolithography process or metal patterns in which two or more metal layers are stacked. The fourth metal layer can include first and second electrodes E11 and E12 of the first TFT TFT1 and first and second electrodes E21 and E22 of the second TFT TFT2. The first and second electrodes E11 and E12 of the first TFT TFT1 can be connected to a first active pattern ACT1 through a first contact hole passing through the insulating layers GI1, ILD1, BUF2, GI2, ILD2 and ILD3. The first and second electrodes E21 and E22 of the second TFT TFT2 can be connected to a second active pattern ACT2 through a second contact hole passing through the insulating layers GI2, ILD2 and ILD3. The first electrode E21 of the second TFT TFT2 can be connected to the light shield pattern BSM through a third contact hole passing through the insulating layers ILD1, BUF2, GI2, ILD2 and ILD3. Here, a strong electric field can be generated in the metal patterns E11 to E22 of the fourth metal layer due to voltages swinging between a gate-on voltage and a gate-off voltage with a large voltage difference.

A first planarization layer PLN1 can cover the patterns E11 to E22 of the fourth metal layer. The first planarization layer PLN1 can thickly cover the display area DA of the circuit layer 12 with an organic insulating material. When the first planarization layer PLN1 is applied on the circuit layer 12, the organic insulating material can flow to the edge of the display panel 100 and cover the side surface of the circuit layer 12.

A fifth metal layer can be formed on the first planarization layer PLN1. The fifth metal layer can be insulated from the fourth metal layer by the first planarization layer PLN1. The fifth metal layer can include a single metal layer patterned in a photolithography process or metal patterns in which two or more metal layers are stacked. The fifth metal layer can include a metal pattern SD2 connecting the light emitting element to the second TFT TFT2. The metal pattern SD2 can be connected to the second electrode E22 of the second TFT TFT2 through a fourth contact hole penetrating the first planarization layer PLN1.

A second planarization layer PLN2 can be formed on the first planarization layer PLN1 to cover the metal patterns of the fifth metal layer. The second planarization layer PLN2 can thickly cover the display area DA of the circuit layer 12 with an organic insulating material. A sixth metal layer can be formed on the second planarization layer PLN2. The second planarization layer PLN2 can planarize the surface on which the sixth metal layer is formed.

The sixth metal layer can include a single metal layer patterned in a photolithography process or metal patterns in which two or more metal layers are stacked. The pattern of the sixth metal layer can include an anode electrode AND of the light emitting device. The anode electrode AND can be in contact with the metal pattern SD2 connected to the second TFT TFT2 of the pixel circuits through the fifth contact hole penetrating the second planarization layer PLN2.

In the light-emitting element layer 14, a bank BNK can be formed on the second planarization layer PLN2 to cover the edge of the anode AND. In this case, the bank BNK can be formed in a pattern that divides a light emitting area (or an opening area) from which light is emitted from each pixel to the outside. Accordingly, the bank BNK can be referred to as a pixel-defining film. The bank BNK can be patterned in a photolithography process by including an organic insulating material having photosensitivity. Further, a spacer SPC having a predetermined height can be formed on the bank BNK. In this case, the bank BNK and the spacer SPC can be integrated with the same organic insulating material. Further, the spacer SPC secures a gap between a fine metal mask (FMM) and the anode electrode AND so that the FMM is not in contact with the anode electrode AND during a deposition process of the light emitting device formed of an organic compound.

A seventh metal layer used as a cathode electrode CAT of the light emitting element can be formed on the light emitting element implemented with the bank BNK and an organic compound layer EL. The seventh metal layer can be connected between sub-pixels in the display area DA. Here, the organic compound layer EL can be referred to as a light emitting layer or an electroluminescent layer.

The encapsulation layer 16 can include multiple insulating layers covering the cathode electrode CAT of the light emitting device. The multiple insulating layers can include a first inorganic insulating layer PAS1 covering the cathode electrode CAT, a thick organic insulating layer PCL covering the first inorganic insulating layer PAS1, and a second inorganic insulating layer PAS2 covering the organic insulating layer PCL.

The touch sensor layer 18 can include a third buffer layer BUF3 covering the second inorganic insulating layer PAS2, a bridge metal BRM arranged on the third buffer layer BUF3, a touch interlayer insulating layer TILD of an inorganic material covering the bridge metal BRM, a touch sensor metal TSM arranged above the bridge metal BRM, and an organic insulating layer PAC covering the touch interlayer insulating layer TILD and the touch sensor metal TSM. Here, the third buffer layer BUF3 can be a touch buffer layer. Here, the refractive index of the touch interlayer insulating layer TILD can be lower than the refractive index of the organic insulating layer PAC. Accordingly, lights passing through the touch interlayer insulating layer TILD can be refracted by the organic insulating layer PAC.

An eighth metal layer used as the bridge metal BRM can be arranged on the third buffer layer BUF3 and can overlap the bank BNK. The eighth metal layer can include a single-metal layer or a stacked-metal layer, comprising two or more metal layers, patterned through the photolithography process.

The ninth metal layer can include a single-metal layer or a stacked-metal layer, comprising two or more metal layers, patterned through the photolithography process. A pattern of the ninth metal layer can include the touch sensor metal TSM. The touch sensor metal TSM can be contacted to the bridge metal BRM through a sixth contact hole through the touch interlayer insulating layer TILD.

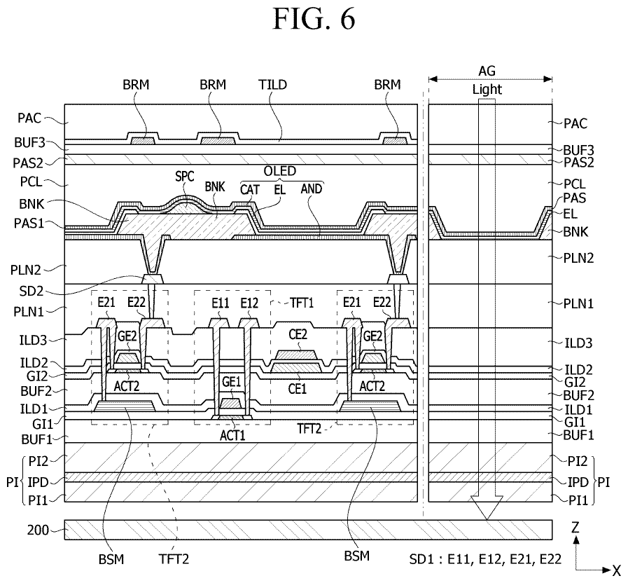

FIG. 6 is a view illustrating a cross-sectional structure of a pixel area and a light transmitting area arranged in the second display area in the display device according to one or more embodiments of the present disclosure.

Referring to FIG. 6, the second display area CA can include the pixel area and the light transmitting area.

The pixel area of the second display area CA can include a substrate PI, a circuit layer 12 on the substrate PI, a light-emitting element layer 14 on the circuit layer 12, an encapsulation layer 16 on the light-emitting element layer 14, and a touch sensor layer 18 on the encapsulation layer 16. Since the substrate PI, the circuit layer 12, the light-emitting element layer 14, the encapsulation layer 16, and the touch sensor layer 18 arranged in the pixel area of the second display area CA are substantially the same in arrangement structure as the pixel area of the first display area DA described in FIG. 5, the same reference numerals are given to them, and redundant descriptions thereof can be omitted or simplified. In this case, referring to FIG. 6, a touch sensor metal TSM can be contacted to the bridge metal BRM through a contact hole through the touch interlayer insulating layer TILD as in FIG. 5, so that the touch sensor metal TSM can be arranged on the bridge metal BRM.

The light transmitting area AG can include transparent medium with high light transmittance without metal so that light can enter with minimal light loss. The light transmitting area AG can be formed of transparent insulating materials without including metal wire or pixels. For example, compared to the pixel area, the light transmitting area AG may not have metallic wires such as anode electrodes AND and cathode electrodes CAT arranged therein. An organic compound layer EL can be arranged in the light transmitting area AG.

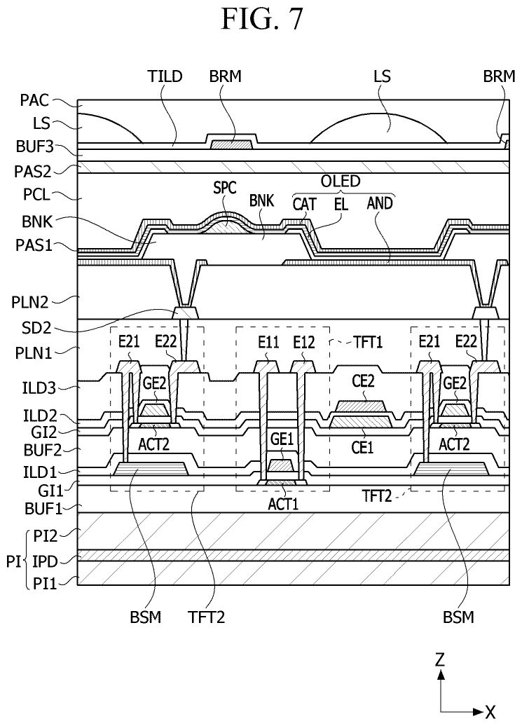

FIG. 7 is a view illustrating a cross-sectional structure of a pixel area arranged in the boundary area BA in the display device according to one or more embodiments of the present disclosure.

Referring to FIG. 7, the boundary area BA can include the pixel area and a light transmitting area.

The pixel area of the boundary area BA can include a substrate PI, a circuit layer 12 on the substrate PI, a light-emitting element layer 14 on the circuit layer 12, an encapsulation layer 16 on the light-emitting element layer 14, and a touch sensor layer 18 on the encapsulation layer 16. Since the substrate PI, the circuit layer 12, the light-emitting element layer 14, the encapsulation layer 16, and the touch sensor layer 18 arranged in the pixel area of the boundary area BA are substantially the same in arrangement structure as the pixel area of the first display area DA described in FIG. 5, the same reference numerals are given to them, and redundant descriptions thereof can be omitted or simplified. In this case, referring to FIG. 7, a touch sensor metal TSM can be contacted to the bridge metal BRM through a contact hole through the touch interlayer insulating layer TILD as in FIG. 5, so that the touch sensor metal TSM can be arranged on the bridge metal BRM.

The boundary area BA can include a lens part LS.

The lens part LS can overlap the light-emitting element (OLED), and the display device can adjust the luminance of the light emitted from the light-emitting element (OLED) by using the lens part LS arranged to overlap the light-emitting element (OLED). For example, the lens part LS having the size equal to or larger than a emission area of the light-emitting element (OLED) can focus lights emitted from the light-emitting element (OLED) to increase the directivity of the light toward the front side of the display panel 100. Here, the front side of the display panel 100 can be a side of the display panel 100 on which an image is displayed. Accordingly, the luminance of the boundary area BA can be higher by the lens part LS having the size equal to or larger than the emission area of the light-emitting element (OLED).

In the case of the lens part LS having the size smaller than the emission area of the light-emitting element (OLED), lights entering the lens LS are focused, whereas lights emitted from the light-emitting element (OLED) and passing through areas outside the lens LS are scattered to reduce the directivity of the light toward the front side of the display panel 100. For example, the smaller the size of the lens part LS than the emission area of the light-emitting element (OLED), the greater the amount of light passing through areas outside the lens part LS. Further, lights passing through areas outside the lens part LS can be refracted by the difference in refractive index between the touch interlayer insulating layer TILD and the organic insulating layer PAC. As a result, the directivity of the light from the light-emitting element (OLED) toward the front side of the display panel 100 can be further reduced, thereby reducing the luminance of the boundary area BA by the lens part LS having the size smaller than the emission area of the light-emitting element (OLED).

Thus, the display device according to an embodiment of the present disclosure can adjust the luminance of the boundary area BA through use of the lens part LS. Accordingly, the display device according to an embodiment of the present disclosure can prevent, reduce, or minimize visibility of the boundary due to the luminance difference between the first display area DA and the second display area CA by using the boundary area BA including the lens part LS.

The lens part LS can be arranged in the touch sensor layer 18. For example, a plurality of lens parts LS can be arranged to be spaced apart from each other on the third buffer layer BUF3 of the touch sensor layer 18.

The lens part LS can be formed in a convex shape toward the front side of the display panel 100. As shown in FIG. 7, the lens part LS can be formed in a semicircular shape or the like in a vertical cross section, but is not necessarily limited thereto. For example, the lens part LS can be formed in a hemispherical shape covering the light-emitting element (OLED), but is not necessarily limited thereto. For example, the lens part LS can be provided in various shapes to adjust the luminance.

The boundary area BA can include, but is not necessarily limited to, the light transmitting area AG. Referring to FIG. 4, the light transmitting area AG can be arranged in the boundary area BA adjacent to the sub-pixels in the boundary area BA. For example, the light transmitting area AG can be arranged between the light-emitting elements (OLED) provided as sub-pixels in the boundary area BA. However, when the first sub-pixel SPXL1 arranged in the first display area DA is used as a sub-pixel of the boundary area BA, since it is difficult to secure a space for arranging the light transmitting area AG, the light transmitting area AG may not be arranged between the sub-pixels of the boundary area BA.

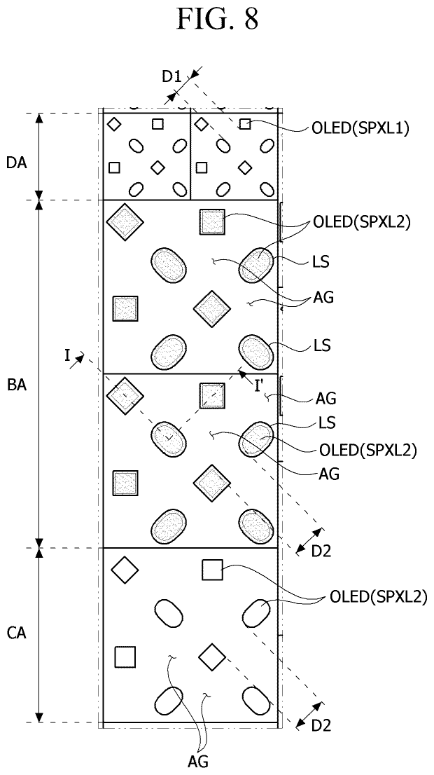

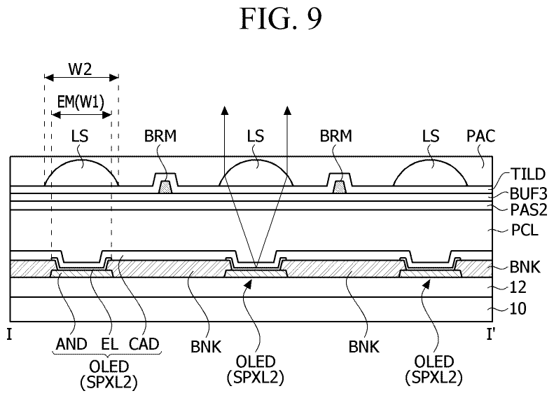

FIG. 8 is a view illustrating a portion of a display panel according to one or more embodiments arranged in the display device according to one or more embodiments of the present disclosure. For example, FIG. 8 is a plan view illustrating a portion of the display panel according to a first embodiment, which is an enlarged view of area A of FIG. 4. FIG. 9 is a view schematically illustrating a cross-section along line I-I′ of FIG. 8. For example, FIG. 9 is a cross-sectional view schematically illustrating an arrangement relationship of the lens part LS and the light-emitting element (OLED) forming the second sub-pixel SPXL2. Further, the arrows shown in FIG. 9 can indicate an optical path of light emitted from the light-emitting element (OLED).

Referring to FIG. 8, in order to ensure the light transmittance of a second display area CA, the number of pixels per unit area (Pixels Per Inch) of the second display area CA can be lower than the number of pixels per unit area (Pixels Per Inch) of the first display area DA. In this case, the number of pixels per unit area (Pixels Per Inch) of the boundary area BA can be the same as the number of pixels per unit area (Pixels Per Inch) of the second display area CA. Further, the second display area CA and a boundary area BA can include a light transmitting area AG.

Further, the size of the light-emitting element (OLED) of the second sub-pixel SPXL2 can be larger than the size of the light-emitting element (OLED) of a first sub-pixel SPXL1. Here, the light-emitting element (OLED) of the first sub-pixel SPXL1 can be a first light-emitting element, and the light-emitting element (OLED) of the second sub-pixel SPXL2 can be a second light-emitting element.

Furthermore, a first spacing D1 of two first light-emitting elements arranged adjacent to each other can be smaller than a spacing D2 of two second light-emitting elements arranged adjacent to each other. In this case, since light-emitting elements arranged in the boundary area BA are also light-emitting elements (OLED) of the second sub-pixel SPXL2, two light-emitting elements (OLED) arranged adjacent to each other in the boundary area BA can be spaced apart by the second spacing D2. In other words, the spacing of the two light-emitting elements (OLED) arranged adjacent to each other in both the second display area CA and the boundary area BA can be the same. Here, the first spacing D1 and the second spacing D2 can be the spacing between two light-emitting elements (OLED) that are arranged adjacent to each other while implementing different colors. Alternatively, the first spacing D1 and the second spacing D2 can represent the minimum spacing or the shortest distance between two light-emitting elements (OLED) arranged adjacent to each other.

Referring to FIG. 9, a lens part LS of the touch sensor layer 18 can overlap the light-emitting element (OLED) on the circuit layer 12. In this case, the light-emitting element (OLED) can include an emission area EA formed by emitting light. Here, the emission area EA can be formed to have a first width W1. Further, the first width W1 of the emission area EA can be, but is not necessarily limited to, the same as the width of the organic compound layer EL. For example, when the light-emitting element (OLED) emits light with the lens part LS removed, the emission width of the light-emitting element (OLED) that is substantially visible from the front side of the display panel 100 can be the first width W1 of the emission area EA.

A second width W2 of the lens part LS can be larger than the first width W1 of the emission area EA. Accordingly, the lens part LS having the width larger than the first width W1 of the emission area EA can focus lights emitted from the light-emitting element (OLED) to increase the directivity of the light toward the front side of the display panel 100, thereby increasing the luminance of the boundary area BA. In this case, the luminance of the boundary area BA can be higher than the luminance of the second display area CA and lower than the luminance of the first display area DA.

Hence, the display device according to the embodiment of the present disclosure causes a blur effect, which improves the luminance of the boundary area BA through use of the lens part LS having the width larger than the first width W1 of the emission area EA, thereby preventing, reducing, or minimizing visibility of the boundary due to the luminance difference between the first display area DA and the second display area CA.

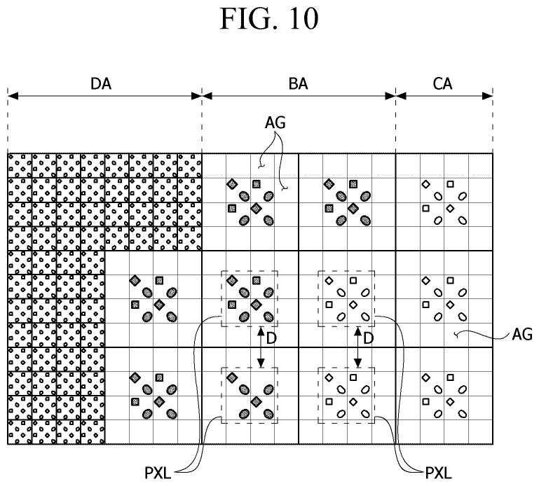

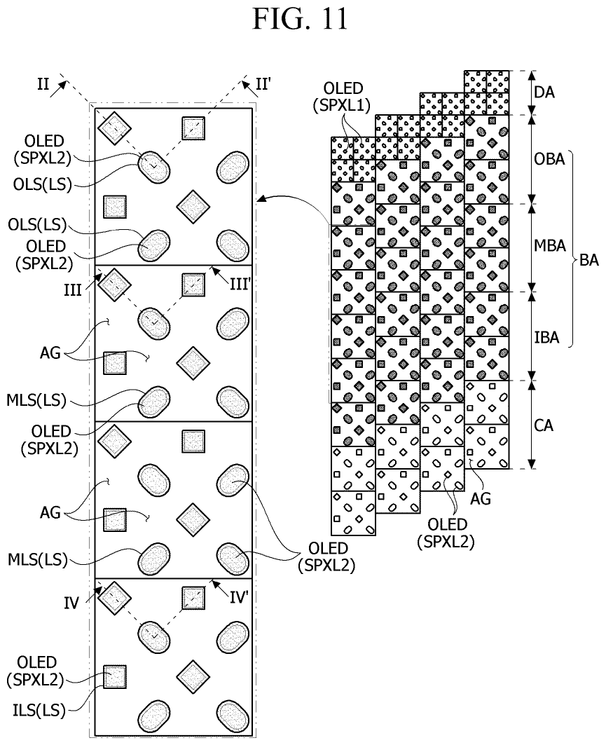

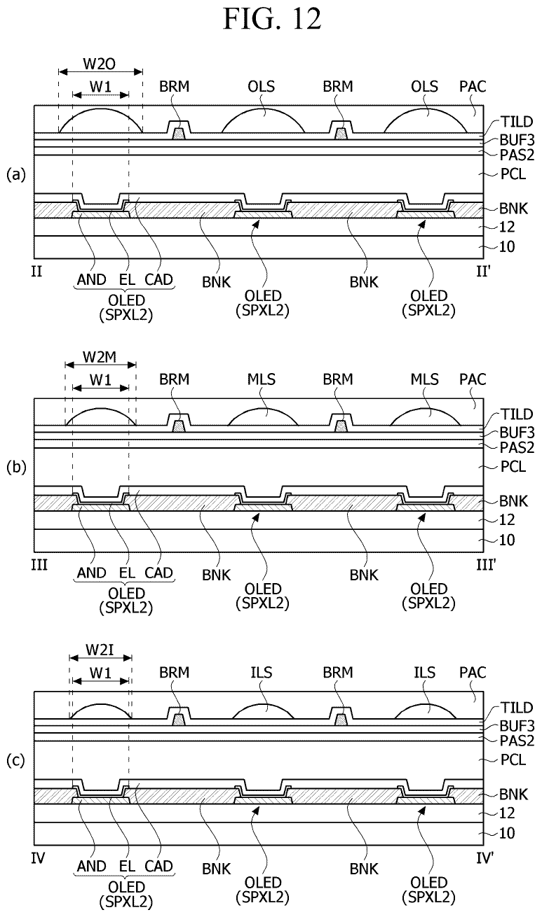

FIG. 10 is a view illustrating a portion of a display panel according to another embodiment arranged in the display device according to one or more embodiments of the present disclosure. For example, FIG. 10 is a view schematically illustrating an arrangement relationship between pixels arranged in each of a first display area DA, a second display area CA, and a boundary area BA.

Referring to FIG. 10, the second display area CA can include a plurality of pixels PXL that are arranged to be spaced apart from each other, and the pixel PXL of the second display area CA can include a plurality of second sub-pixels SPXL2. In this case, the pixels PXL of the second display area CA that are arranged adjacent to each other can be arranged to be spaced apart by a predetermined spacing distance D.

The boundary area BA can include a plurality of pixels PXL that are arranged to be spaced apart from each other, and the pixel PXL of the boundary area BA can include a plurality of second sub-pixels SPXL2. In this case, the pixels PXL of the boundary area BA that are arranged adjacent to each other can be arranged to be spaced apart by a predetermined spacing distance D. Further, a lens part LS can be arranged on the second sub-pixel SPXL2.

Thus, since the pixels PXL arranged in the second display area CA and the boundary area BA are spaced apart by a predetermined spacing distance D, the display device according to the embodiment of the present disclosure can increase the light transmittance in the second display area CA and the boundary area BA.

FIG. 11 is a view illustrating a portion of the display panel according to another embodiment arranged in the display device according to one or more embodiments of the present disclosure. For example, FIG. 11 is a plan view illustrating a portion of the display panel according to a second embodiment, which can show a boundary area BA according to the second embodiment. FIG. 12 is a view schematically illustrating a cross-section of a subdivided boundary area of FIG. 11. Particularly, (a) of FIG. 12 is a view schematically illustrating a cross-section along line II-II′ of FIG. 11, (b) of FIG. 12 is a view schematically illustrating a cross-section along line III-III′ of FIG. 11, and (c) of FIG. 12 is a view schematically illustrating a cross-section along line IV-IV′ of FIG. 11.

In the display panel according to the second embodiment, since areas other than the boundary area BA according to the second embodiment are substantially the same as those in the display panel according to the first embodiment, the same reference numerals are given to them, and redundant descriptions thereof can be omitted or simplified.

Referring to FIG. 11, the boundary area BA can be further subdivided according to the size of a lens part LS to further prevent, reduce, or minimize visibility of the boundary between the first display area DA and the second display area CA. In this case, the number of pixels per unit area (Pixels Per Inch) of the boundary area BA can be the same as the number of pixels per unit area (Pixels Per Inch) of the second display area CA. Further, the width of the lens part LS can be formed smaller toward the second display area CA. Accordingly, the luminance of the boundary area BA can be lower toward the second display area CA, thereby further preventing, reducing, or minimizing the boundary visibility between the first display area DA and the second display area CA.

The boundary area BA can include an inner boundary area IBA and an outer boundary area OBA. The boundary area BA can further include a middle boundary area MBA arranged between the inner boundary area IBA and the outer boundary area OBA. For example, based on the center of the second display area CA, the middle boundary area MBA can be arranged inside the outer boundary area OBA, and the inner boundary area IBA can be arranged inside the middle boundary area MBA. In this case, compared to the middle boundary area MBA, the inner boundary area IBA can be a boundary area BA arranged closer to the second display area CA. Here, the term “inside” can refer to a direction pointing towards the center C of the second display area CA, Further, conversely, “outside” indicates a direction opposite to the “inside”.

The inner boundary area IBA can include an inner lens part ILS overlapping the light-emitting element (OLED), the middle boundary area MBA can include a middle lens part MLS overlapping the light-emitting element (OLED), and the outer boundary area OBA can include an outer lens part OLS overlapping the light-emitting element (OLED). Accordingly, the lens part LS of the boundary area BA can include the inner lens part ILS, the middle lens part MLS, and the outer lens part OLS.

Referring to FIGS. 11 and 12, the size of the inner lens part ILS can be formed smaller than the size of the middle lens part MLS, and the size of the middle lens part MLS can be formed smaller than the size of the outer lens part OLS. In this case, the size of the inner lens part ILS, the size of the middle lens part MLS, and the size of the outer lens part OLS can be formed larger than the size of the emission area EA of the light-emitting element (OLED). For example, the width W2I of the inner lens part ILS can be formed smaller than the width W2M of the middle lens part MLS, and the width W2M of the middle lens part MLS can be formed smaller than the width W2O of the outer lens part OLS. In this case, the width W2I of the inner lens part ILS, the width W2M of the middle lens part MLS, and the width W2O of the outer lens part OLS are formed larger than the first width W1 of the emission area EA of the light-emitting element (OLED).

Accordingly, since a display device including the display panel according to the second embodiment can use the outer lens part OLS, the middle lens part MLS and the inner lens part ILS, which are sequentially formed smaller toward the second display area CA, the luminance of the boundary area BA can be lower toward the second display area CA. As a result, visibility of the boundary between the first display area DA and the second display area CA can be further prevented, reduced, or minimized.

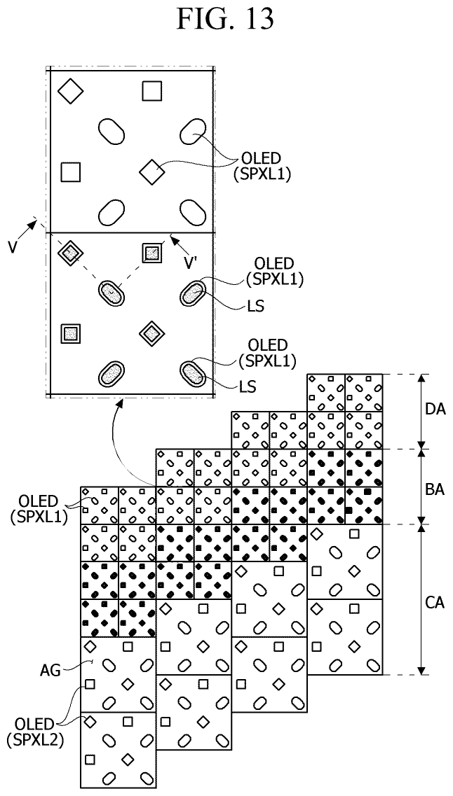

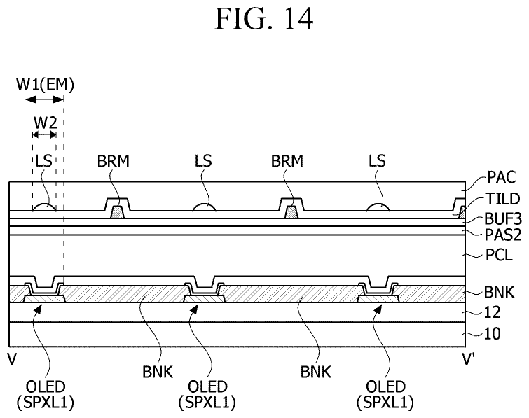

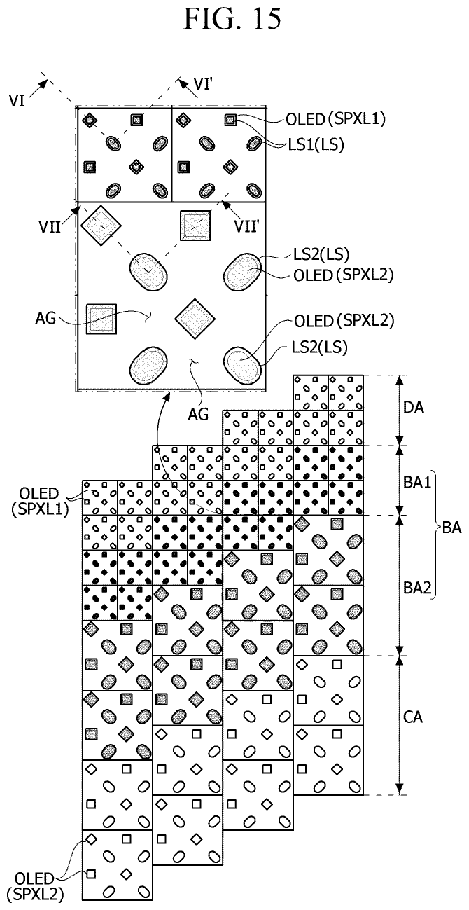

FIG. 13 is a view illustrating a portion of a display panel according to another embodiment arranged in the display device according to one or more embodiments of the present disclosure. For example, FIG. 13 is a plan view illustrating a portion of the display panel according to a third embodiment, which can show a boundary area BA according to the third embodiment. FIG. 14 is a view schematically illustrating a cross-section along line V-V′ of FIG. 13. For example, FIG. 14 is a cross-sectional view schematically illustrating an arrangement relationship of a lens part LS and the light-emitting element (OLED) of the first sub-pixel SPXL1. Further, the arrows shown in FIG. 14 can indicate an optical path of light emitted from the light-emitting element (OLED).

In the display panel according to the third embodiment, since areas other than the boundary area BA according to the third embodiment are substantially the same as those in the display panel according to the first embodiment, the same reference numerals are given to them, and redundant descriptions thereof can be omitted or simplified.

Referring to FIGS. 13 and 14, the boundary area BA according to the third embodiment can be formed by the light-emitting element (OLED) of the first sub-pixel SPXL1, and the lens part LS overlapping the light-emitting element (OLED) of the first sub-pixel SPXL1. For example, the boundary area BA according to the third embodiment can include the light-emitting element (OLED) of the first sub-pixel SPXL1, and the lens part LS overlapping the light-emitting element (OLED) of the first sub-pixel SPXL1. In this case, the number of pixels per unit area (Pixels Per Inch) of the boundary area BA can be the same as the number of pixels per unit area (Pixels Per Inch) of the first display area DA.

The lens part LS of the boundary area BA according to the third embodiment can be formed smaller than the emission area EM of the light-emitting element (OLED) of the first sub-pixel SPXL1, so that the luminance of the boundary area BA can be lower than the luminance of the first display area DA. For example, the emission area EA of the light-emitting element (OLED) forming the first sub-pixel SPXL1 can be formed to have a first width W1, and the lens part LS overlapping the light-emitting element (OLED) of the first sub-pixel SPXL1 can be formed to have a second width W2 smaller than the first width W1. Accordingly, the lens part LS overlapping the light-emitting element (OLED) of the first sub-pixel SPXL1 can lower the luminance in the boundary area BA.

As the size of the lens part LS is smaller than the emission area of the light-emitting element (OLED), the amount of light passing through areas outside the lens part LS can increase, and lights passing through areas outside the lens part LS can be refracted by the difference in refractive index between the touch interlayer insulating layer TILD and the organic insulating layer PAC, so that the directivity of the light from the light-emitting element (OLED) toward the front side of the display panel 100 can be reduced. Accordingly, the lens part LS having the size smaller than the emission area EM of the light-emitting element (OLED) forming the first sub-pixel SPXL1 can lower the luminance of the boundary area BA than the luminance of the first display area DA.

As a result, the boundary area BA according to the third embodiment can lower the luminance of the boundary area BA than the luminance of the first display area DA by the lens part LS having the size smaller than the emission area EM of the light-emitting element (OLED) forming the first sub-pixel SPXL1. Accordingly, the boundary area BA according to the third embodiment can prevent, reduce, or minimize visibility of the boundary between the first display area DA and the second display area CA.

FIG. 15 is a view illustrating a portion of a display panel according to another embodiment arranged in the display device according to one or more embodiments of the present disclosure. For example, FIG. 15 is a plan view illustrating a portion of the display panel according to a fourth embodiment, which can show a boundary area BA according to the fourth embodiment. FIG. 16 is a view schematically illustrating a cross-section of a subdivided boundary area of FIG. 15. For example, FIG. 16 is a view schematically illustrating a cross-section of a first boundary area including a first lens part LS1 arranged above the light-emitting element (OLED) of the first sub-pixel SPXL1, and a second boundary area including a second lens part LS2 arranged above the light-emitting element (OLED) of the second sub-pixel SPXL2. Particularly, (a) of FIG. 16 is a view schematically illustrating a cross-section along line VI-VI′ of FIG. 15, and (b) of FIG. 16 is a view schematically illustrating a cross-section along line VII-VII′ of FIG. 15. Further, the arrows shown in (a) of FIG. 16 and (b) of FIG. 16 can indicate an optical path of light emitted from the light-emitting element (OLED).

In the display panel according to the fourth embodiment, since areas other than the boundary area BA according to the fourth embodiment are substantially the same as those in the display panel according to the first embodiment, the same reference numerals are given to them, and redundant descriptions thereof can be omitted or simplified.

Referring to FIGS. 15 and 16, the boundary area BA can include a first boundary area BA1 arranged adjacent to the first display area DA and a second boundary area BA2 arranged adjacent to the second display area CA. Here, based on the center C of the second display area CA, the second boundary area BA2 can be arranged inside the first boundary area BA1. Further, the number of pixels per unit area (Pixels Per Inch) of the first boundary area BA1 can be the same as the number of pixels per unit area (Pixels Per Inch) of the first display area DA. Further, the number of pixels per unit area (Pixels Per Inch) of the second boundary area BA2 can be the same as the number of pixels per unit area (Pixels Per Inch) of the second display area CA.

A lens part LS of the boundary area BA can include a first lens part LS1 of the first boundary area BA1 and a second lens part LS2 of the second boundary area BA2.

The first lens part LS1 and the second lens part LS2 can be different in size. For example, the size of the first lens part LS1 can be smaller than the size of the second lens part LS2. More specifically, the width of the first lens part LS1 can be smaller than the width of the second lens part LS2.

The first boundary area BA1 can include the light-emitting element (OLED) of the first sub-pixel SPXL1, and the first lens part LS1 overlapping the light-emitting element (OLED) of the first sub-pixel SPXL1.

The first lens part LS1 can be formed smaller than the emission area EM of the light-emitting element (OLED) of the first sub-pixel SPXL1, so that the luminance of the first boundary area BA1 can be lower than the luminance of the first display area DA. For example, the width of the first lens part LS1 can be formed smaller than the width of the emission area EM of the light-emitting element (OLED) forming the first sub-pixel SPXL1, so that the luminance in the first boundary area BA1 can be formed lower than the luminance in the first display area DA. Here, the light-emitting element (OLED) in the first boundary area BA1 can be substantially the same as the light-emitting element (OLED) in the first display area DA, and thus can be a first light-emitting element. In this case, the light-emitting elements (OLED) in the first boundary area BA1 can be spaced apart by the first spacing D1.

The second boundary area BA2 can include the light-emitting element (OLED) of the second sub-pixel SPXL2, and a second lens part LS2 overlapping the light-emitting element (OLED) of the second sub-pixel SPXL2. In this case, the second lens part LS2 can be larger than the first lens part LS1. Further, the second lens part LS2 can be formed larger than the emission area EM of the light-emitting element (OLED) of the second sub-pixel SPXL2, so that the luminance of the second boundary area BA2 can be formed higher than the luminance in the second display area CA and lower than the luminance in the first boundary area BA1. Here, the light-emitting element (OLED) in the second boundary area BA2 can be substantially the same as the light-emitting element (OLED) in the second display area CA, and thus can be a second light-emitting element. In this case, the light-emitting elements (OLED) in the second boundary area BA2 can be spaced apart by the second spacing D2.

Accordingly, in the boundary area BA according to the fourth embodiment, considering that the luminance can be lower when the size of the lens part LS is smaller than the emission area EM and can be higher the luminance when the size of the lens part LS is larger than the emission area EM, the size of the first lens part LS1 can be formed smaller than the size of the second lens part LS2.

Accordingly, in the display device according to an embodiment of the present disclosure, the number of pixels per unit area of the first display area DA, the first boundary area BA1, the second boundary area BA2, and the second display area CA, the size of the first lens part LS1 of the first boundary area BA1, the size of the second lens part LS2 of the second boundary area BA2, and the like can be adjusted to prevent, reduce, or minimize visibility of the boundary between the first display area DA and the second display area CA due to the luminance difference between the first display area DA and the second display area CA. For example, the luminance of the second boundary area BA2 can be formed lower than the luminance of the first boundary area BA1, and can be formed higher than the luminance of the second display area CA. Further, the luminance of the first boundary area BA1 can be formed lower than the luminance of the first display area DA. Accordingly, the display device according to the embodiment of the present disclosure can use the first boundary area BA1 and the second boundary area BA2 to prevent, reduce, or minimize visibility of the boundary due to the luminance difference between the first display area DA and the second display area CA.

Referring to FIGS. 8 to 16, the light-emitting elements (OLED) arranged in each of the first display area DA, the second display area CA, and the boundary area BA can be spaced apart by a predetermined spacing distance. Accordingly, since lights passing through areas outside the lens part LS can be refracted by the difference in refractive index between the touch interlayer insulating layer TILD and the organic insulating layer PAC, if the refracted lights can be refracted toward the front side of the display panel 100, the luminance of the first display area DA, the second display area CA, and the boundary area BA can be improved. This improvement in luminance can allow for low power operation of the display device.

Therefore, in the display device according to the embodiment of the present disclosure, a dummy lens part can be arranged between lens parts LS overlapping the light-emitting elements (OLED), thereby refracting lights emitted from the light-emitting elements (OLED) and passing through areas outside the lens part LS toward the front side of the display panel 100.

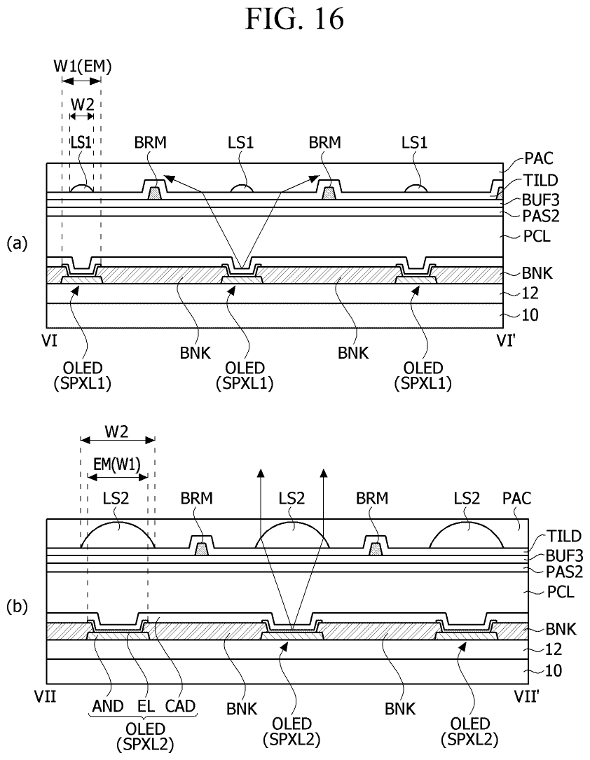

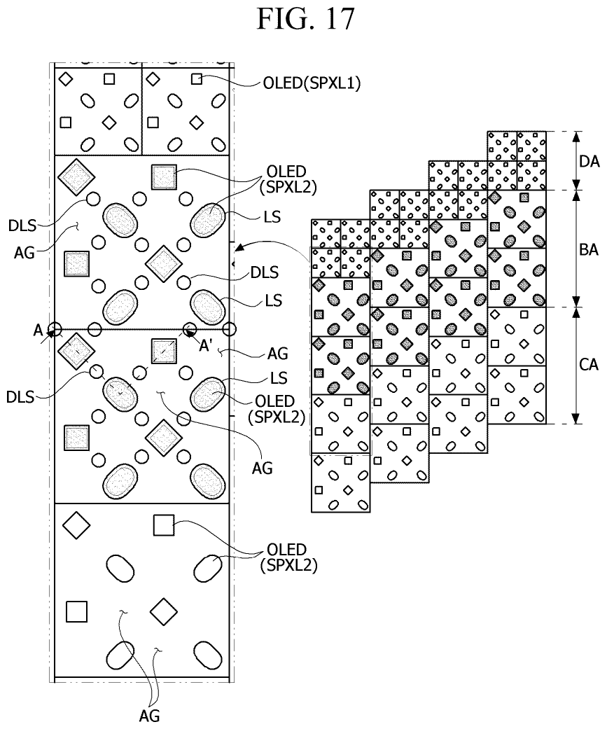

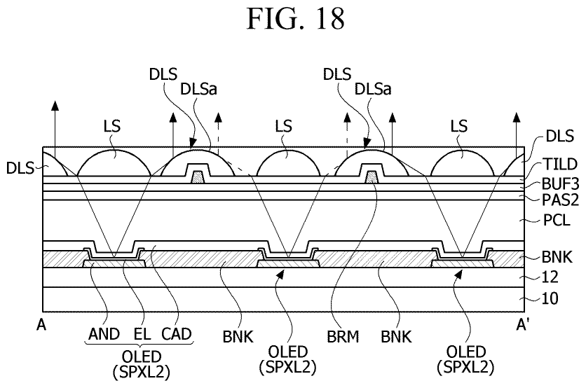

FIG. 17 is a view illustrating a portion of a display panel according to another embodiment arranged in the display device according to one or more embodiments of the present disclosure. For example, FIG. 17 is a plan view illustrating a portion of the display panel according to a fifth embodiment, which can show a boundary area BA according to the fifth embodiment. FIG. 18 is a view schematically illustrating a cross-section along line A-A′ of FIG. 17. For example, FIG. 18 is a cross-sectional view schematically illustrating an arrangement relationship of the light-emitting elements (OLED) of a lens part LS and a dummy lens part DLS. Further, the arrows shown in FIG. 18 can indicate an optical path of light emitted from the light-emitting element (OLED).

Referring to FIGS. 17 and 18, the display panel 100 arranged in a display device according to the embodiment of the present disclosure can include a first display area DA, a second display area CA, and a boundary area BA. Further, comparing the boundary area BA described in FIG. 7 with the boundary area BA shown in FIG. 18, the boundary area BA shown in FIG. 18 further includes the dummy lens part DLS, and therefore redundant descriptions of other components other than the dummy lens part DLS can be omitted or simplified.

Referring to FIGS. 17 and 18, the boundary area BA according to a fifth embodiment can further include the dummy lens part DLS in addition to the lens part LS.

A plurality of dummy lens parts DLS can be arranged to be spaced apart from each other on the touch interlayer insulating layer TILD of the touch sensor layer 18.

The dummy lens part DLS and the lens part LS can be located in the same layer, or the dummy lens part DLS can be arranged between two neighboring lens parts LS.

The position of the dummy lens part DLS, which is located between two neighboring lens parts LS, can be set in consideration of its arrangement relationship with the light transmitting area AG. For example, in consideration of the light transmittance through the light transmitting area AG, the type of optical device 200 and the like, the dummy lens part DLS can be arranged to minimize interference with light passing through the light transmitting area AG, but is not necessarily limited thereto.

Referring to FIG. 17, the dummy lens part DLS can be arranged between the two light-emitting elements (OLED) that are arranged at the shortest distance. For example, since it is difficult to arrange the light transmitting area AG between the two light-emitting elements (OLED) arranged at the shortest distance due to the disposition position, the dummy lens part DLS can be arranged between the two light-emitting elements (OLED) spaced apart by the second spacing D2. Accordingly, interferences between lights passing through the light transmitting area AG and the dummy lens part DLS can be minimized. Here, the second spacing D2 can be the shortest distance between the two light-emitting elements (OLED).

The dummy lens part DLS can be arranged to overlap the bank BNK of the light-emitting element layer 14. Therefore, the dummy lens part DLS may not overlap the light-emitting element (OLED) and thus can refract lights passing through areas outside the lens part LS. Further, the dummy lens part DLS overlapping the bank BNK can minimize interference with lights passing through the light transmitting area AG.

The dummy lens part DLS can be arranged on the touch interlayer insulating film TILD to overlap the bridge metal BRM of the touch sensor layer 18. Here, the bridge metal BRM can be formed of a metallic material, so that it can be arranged to not overlap the light-emitting element (OLED) and the light-transmitting area AG. Furthermore, the bridge metal BRM can be arranged to overlap the bank BNK. Accordingly, the dummy lens part DLS can overlap the bank BNK and the bridge metal BRM. In this case, referring to FIG. 18, the touch sensor metal TSM can be contacted to the bridge metal BRM through the contact hole through the touch interlayer insulating layer TILD, so that the touch sensor metal TSM can be arranged on the bridge metal BRM. Accordingly, the dummy lens part DLS can be arranged on the touch sensor metal TSM of the touch sensor layer 18. Further, the arrangement relationship of the dummy lens part DLS and the touch sensor metal TSM of the touch sensor layer 18 can also apply to the dummy lens part DLS described below.

Referring to FIG. 18, the dummy lens part DLS can be arranged to be spaced apart from the lens part LS by a predetermined interval. Here, the lens part LS and the dummy lens part DLS can be formed in the same or similar shape, and can be formed of a material having the same refractive index, but are not necessarily limited thereto. In this case, the refractive index of the lens part LS and the dummy lens part DLS can be different from the refractive index of the organic insulating layer PAC.

Some of the lights emitted from the light-emitting element (OLED) can be irradiated through a space between the lens part LS and the dummy lens part DLS. In this case, lights passing through the space can be refracted by the difference in refractive index between the touch interlayer insulating layer TILD and the organic insulating layer PAC, and the refracted lights can be refracted toward the front side of the display panel 100 by the outer surface DLSa of the dummy lens part DLS. Accordingly, the luminance at the boundary area BA can be improved.

Therefore, in the display device according to the embodiment of the present disclosure, the dummy lens part DLS can be arranged between lens parts LS overlapping the light-emitting elements (OLED), and thus can refract lights emitted from the light-emitting elements (OLED) and passing through areas outside the lens part LS toward the front side of the display panel 100 to improve the luminance in the boundary area BA.

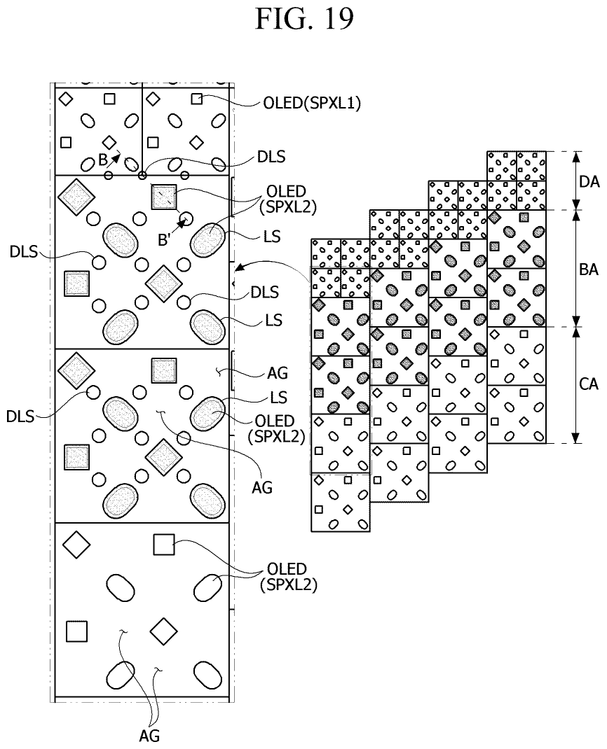

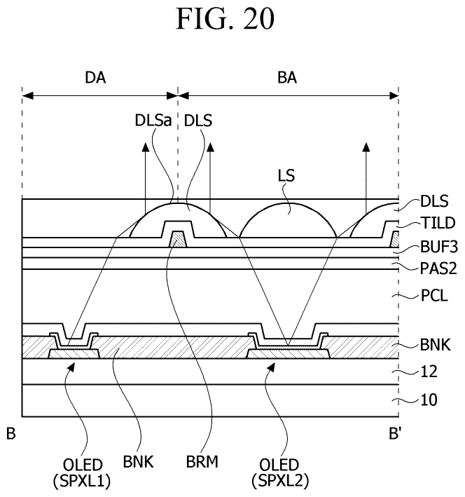

FIG. 19 is a view illustrating another embodiment of a dummy lens part arranged in the display device according to one or more embodiments of the present disclosure. For example, FIG. 19 is a plan view of a portion of a display panel according to a sixth embodiment, which can show the dummy lens part DLS located at the boundary between a boundary area BA and a first display area DA. FIG. 20 is a view schematically illustrating a cross-section along line B-B′ of FIG. 19. FIG. 20 is a cross-sectional view schematically illustrating the dummy lens part DLS located at the boundary between the boundary area BA and the first display area DA in a plane. Further, the arrows shown in FIG. 20 can indicate an optical path of light emitted from the light-emitting element (OLED).

Referring to FIGS. 19 and 20, the dummy lens part DLS can be located at the boundary of the boundary area BA and the first display area DA in a plane. Further, the dummy lens part DLS can be further arranged between two lens parts LS arranged in the boundary area BA, such as the dummy lens part DLS in the boundary area BA according to the fifth embodiment shown in FIGS. 17 and 18.

Referring to FIGS. 19 and 20, the dummy lens part DLS can be arranged between the light-emitting element (OLED) in the boundary area BA and the light-emitting element (OLED) arranged in the first display area DA in a plane. In this case, the lens part LS may not be arranged above the light-emitting element (OLED) forming the first sub-pixel SPXL1 of the first display area DA. Further, the dummy lens part DLS can be arranged to overlap the bank BNK arranged between the light-emitting element (OLED) of the boundary area BA and the light-emitting element (OLED) of the first display area DA in a plane.

Some of lights emitted from the light-emitting element (OLED) of the boundary area BA can be irradiated through the space between the lens part LS and the dummy lens part DLS located at the boundary between the boundary area BA and the first display area DA. In this case, lights passing through the space can be refracted by the difference in refractive index between the touch interlayer insulating layer TILD and the organic insulating layer PAC, and the refracted lights can be refracted toward the front side of the display panel 100 by the outer surface DLSa of the dummy lens part DLS. Accordingly, the luminance at the boundary between the boundary area BA and the first display area DA can be improved by the dummy lens part DLS.

Thus, in the display device according to the embodiment of the present disclosure, the dummy lens part DLS located at the boundary between the boundary area BA and the first display area DA can be used to improve the luminance at the boundary of the boundary area BA and the first display area DA. Accordingly, the display device according to the embodiment of the present disclosure can further prevent, reduce, or minimize visibility of the boundary due to the luminance difference between the first display area DA and the second display area CA.

The dummy lens part DLS located at the boundary between the boundary area BA and the first display area DA can also be applied to the display device according to an embodiment of the present disclosure described below.

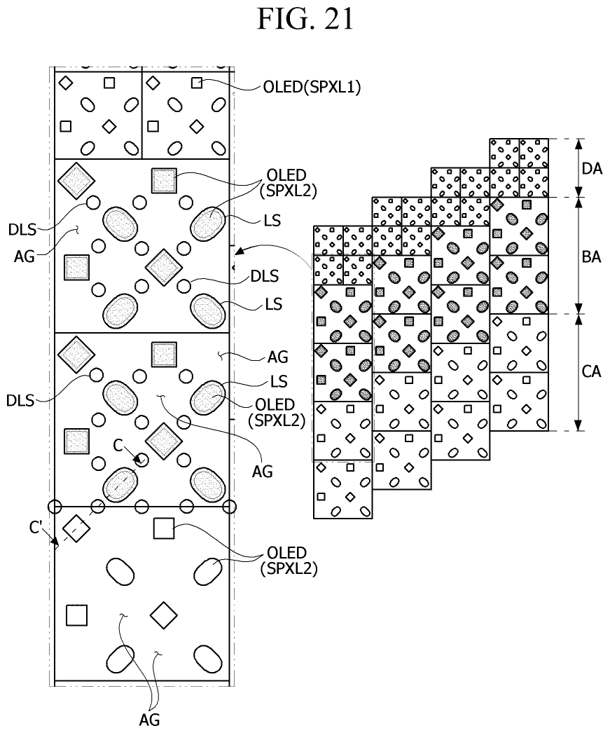

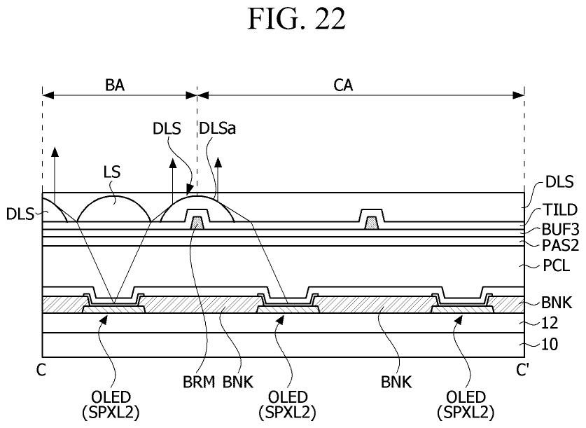

FIG. 21 is a view illustrating another embodiment of a dummy lens part arranged in the display device according to one or more embodiments of the present disclosure. For example, FIG. 21 is a plan view of a portion of a display panel according to a seventh embodiment, which can show the dummy lens part DLS located at the boundary between a boundary area BA and a second display area CA. FIG. 22 is a view schematically illustrating a cross-section along line C-C′ of FIG. 21. FIG. 22 is a cross-sectional view schematically illustrating the dummy lens part DLS located at the boundary between the boundary area BA and the second display area CA in a plane. Further, the arrows shown in FIG. 22 can indicate an optical path of light emitted from the light-emitting element (OLED).

Referring to FIGS. 21 and 22, the dummy lens part DLS can be located at the boundary of the boundary area BA and the second display area CA in a plane. Further, the dummy lens part DLS can be further arranged between two lens parts LS arranged in the boundary area BA, such as the dummy lens part DLS of the boundary area BA according to the fifth embodiment shown in FIGS. 17 and 18.

The dummy lens part DLS can be arranged between the light-emitting element (OLED) of the boundary area BA and the light-emitting element (OLED) arranged in the second display area CA in a plane. In this case, the lens part LS may not be arranged above the light-emitting element (OLED) forming the second sub-pixel SPXL2 of the second display area CA. Further, the dummy lens part DLS can be arranged to overlap the bank BNK arranged between the light-emitting element (OLED) of the boundary area BA and the light-emitting element (OLED) of the second display area CA.

Some of lights emitted from the light-emitting element (OLED) of the boundary area BA can be irradiated through the space between the lens part LS and the dummy lens part DLS located at the boundary between the boundary area BA and the second display area CA. In this case, lights passing through the space can be refracted by the difference in refractive index between the touch interlayer insulating layer TILD and the organic insulating layer PAC, and the refracted lights can be refracted toward the front side of the display panel 100 by the outer surface DLSa of the dummy lens part DLS. Accordingly, the luminance at the boundary between the boundary area BA and the second display area CA can be improved by the dummy lens part DLS.

Thus, in the display device according to the embodiment of the present disclosure, the dummy lens part DLS located at the boundary between the boundary area BA and the second display area CA can be used to improve the luminance at the boundary of the boundary area BA and the second display area CA. Accordingly, the display device according to the embodiment of the present disclosure can further prevent, reduce, or minimize visibility of the boundary due to the luminance difference between the first display area DA and the second display area CA.

The dummy lens part DLS located at the boundary between the boundary area BA and the second display area CA can also be applied to the display device according to an embodiment of the present disclosure described below.

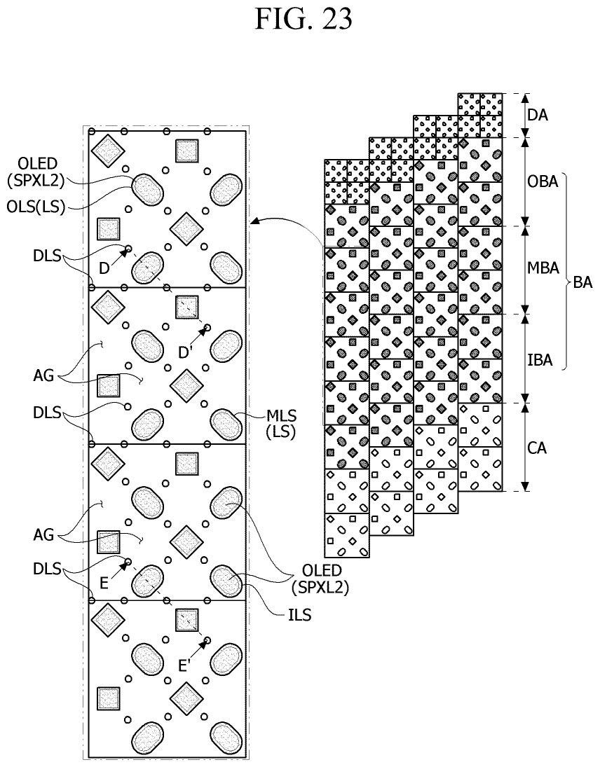

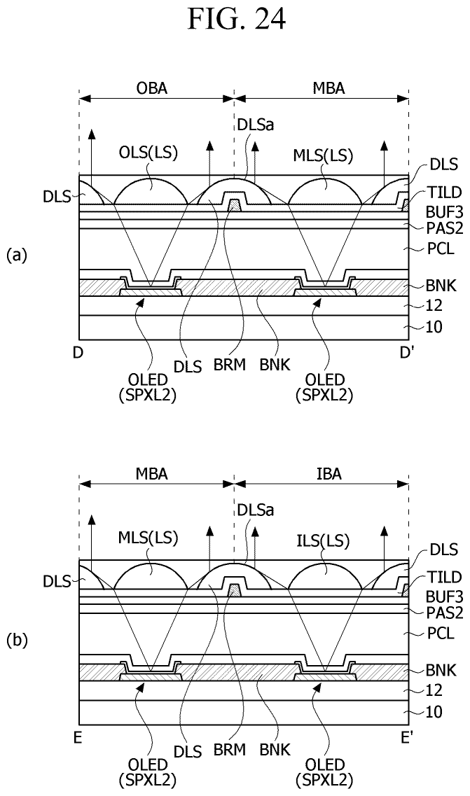

FIG. 23 is a view illustrating another embodiment of a dummy lens part arranged in the display device according to one or more embodiments of the present disclosure. For example, FIG. 23 is a plan view of a portion of a display panel according to an eighth embodiment, which can show dummy lens parts DLS located in an inner boundary area IBA, a middle boundary area MBA, and an outer boundary area OBA. FIG. 24 is a view schematically illustrating a cross-section of a subdivided boundary area of FIG. 23. FIG. 24 at (a) is a view schematically illustrating a cross-section along line D-D′ of FIG. 23. FIG. 24 at (b) is a view schematically illustrating a cross-section along line E-E′ of FIG. 23. Further, the arrows shown in FIG. 24 can indicate an optical path of light emitted from the light-emitting element (OLED).

The display panel 100 arranged in a display device according to the embodiment of the present disclosure can include a first display area DA, a second display area CA, and a boundary area BA. Further, comparing the boundary area BA described in FIG. 11 with the boundary area BA shown in FIG. 23, the boundary area BA shown in FIG. 23 further includes the dummy lens part DLS, and therefore redundant descriptions of other components other than the dummy lens part DLS can be omitted or simplified.

Referring to FIGS. 23 and 24, the dummy lens part DLS can be located in each of the subdivided boundary areas IBA, MBA and OBA.

The boundary area BA can include the inner boundary area IBA, the outer boundary area OBA, and the middle boundary area MBA, and the dummy lens part DLS can be arranged in each of the inner boundary area IBA, outer boundary area OBA, and middle boundary area MBA, but is not limited thereto.

The dummy lens part DLS can be arranged between the light-emitting elements (OLED) of the inner boundary area IBA, the outer boundary area OBA, and the middle boundary area MBA in a plane. In this case, a lens part LS can be arranged above the light-emitting element (OLED) of each of the inner boundary area IBA, the outer boundary area OBA, and the middle boundary area MBA. Further, the dummy lens part DLS can overlap the bank BNK arranged between the light-emitting elements (OLED). Further, the dummy lens part DLS can be arranged on the touch interlayer insulating film TILD to overlap the bridge metal BRM of the touch sensor layer 18. In this case, a touch sensor metal TSM can be contacted to the bridge metal BRM through a contact hole through the touch interlayer insulating layer TILD, so that the touch sensor metal TSM can be arranged on the bridge metal BRM. Accordingly, the dummy lens part DLS can be arranged on the touch sensor metal TSM of the touch sensor layer 18.

The size of an inner lens part ILS arranged in the inner boundary area IBA, the size of a middle lens part MLS arranged in the middle boundary area MBA, and the size of an outer lens part OLS arranged in the outer boundary area OBA can be formed larger than the size of the emission area EA of the light-emitting element (OLED). Further, the size of the middle lens part MLS can be formed larger than the size of the inner lens part ILS, and can be formed smaller than the size of the outer lens part OLS.

The dummy lens part DLS can be arranged between the inner lens parts ILS of the inner boundary area IBA. Further, the size of the dummy lens part DLS arranged between the inner lens parts ILS can be the same as the size of the inner lens parts ILS, but is not necessarily limited thereto.

The dummy lens part DLS can be arranged between the middle lens parts MLS of the middle boundary area MBA. Further, the size of the dummy lens part DLS arranged between the middle lens parts MLS can be the same as the size of the middle lens parts MLS, but is not necessarily limited thereto.

The dummy lens part DLS can be arranged between the outer lens parts OLS of the outer boundary area OBA. Further, the size of the dummy lens part DLS arranged between the outer lens parts OLS can be the same as the size of the middle lens part MLS, but is not necessarily limited thereto.

The dummy lens part DLS can also be arranged at the boundary between the inner boundary area IBA and the middle boundary area MBA. For example, the dummy lens part DLS can be arranged between the inner lens part ILS of the inner boundary area IBA and the middle lens part MLS of the middle boundary area MBA.

Some of lights emitted from the light-emitting element (OLED) of the inner boundary area IBA and/or the middle boundary area MBA can be irradiated through the space between the inner lens part ILS and the dummy lens part DLS or the space between the middle lens part MLS and the dummy lens part DLS. In this case, lights passing through the space can be refracted by the difference in refractive index between the touch interlayer insulating layer TILD and the organic insulating layer PAC, and the refracted lights can be refracted toward the front side of the display panel 100 by the outer surface DLSa of the dummy lens part DLS. Accordingly, the luminance at the boundary between the inner boundary area IBA and the middle boundary area MBA can be improved by the dummy lens part DLS. Here, the size of the dummy lens part DLS arranged at the boundary between the inner boundary area IBA and the middle boundary area MBA can be the same as the size of the middle lens part MLS, but is not necessarily limited thereto.

The dummy lens part DLS can also be arranged at the boundary of the outer boundary area OBA and the middle boundary area MBA. For example, the dummy lens part DLS can be arranged between the outer lens part OLS of the outer boundary area OBA and the middle lens part MLS of the middle boundary area MBA. In this case, the dummy lens part DLS arranged at the boundary between the outer boundary area OBA and the middle boundary area MBA can have the same size as the outer lens part OLS, but is not necessarily limited thereto.

Some of lights emitted from the light-emitting element (OLED) of the outer boundary area OBA and/or the middle boundary area MBA can be irradiated through the space between the outer lens part OLS and the dummy lens part DLS or the space between the middle lens part MLS and the dummy lens part DLS. In this case, lights passing through the space can be refracted by the difference in refractive index between the touch interlayer insulating layer TILD and the organic insulating layer PAC, and the refracted lights can be refracted toward the front side of the display panel 100 by the outer surface DLSa of the dummy lens part DLS. Accordingly, the luminance at the boundary between the outer boundary area OBA and the middle boundary area MBA can be improved by the dummy lens part DLS. Here, the dummy lens part DLS arranged at the boundary between the outer boundary area OBA and the middle boundary area MBA can have the same size as the outer lens part OLS, but is not necessarily limited thereto.

Thus, in the display device according to the embodiment of the present disclosure, the dummy lens parts DLS located in the inner boundary area IBA, the middle boundary area MBA, and the outer boundary area OBA can be used to improve the luminance at the inner boundary area IBA, the middle boundary area MBA, and the outer boundary area OBA. Furthermore, in the display device according to the embodiment of the present disclosure, the dummy lens part DLS located at the boundary between the inner boundary area IBA and the middle boundary area MBA and/or the dummy lens part DLS located at the boundary between the outer boundary area OBA and the middle boundary area MBA can be used to further improve the luminance at the boundary between the inner boundary area IBA and the middle boundary area MBA and/or the luminance at the boundary between the outer boundary area OBA and the middle boundary area MBA. Accordingly, the display device according to the embodiment of the present disclosure can further prevent, reduce, or minimize visibility of the boundary due to the luminance difference between the first display area DA and the second display area CA.

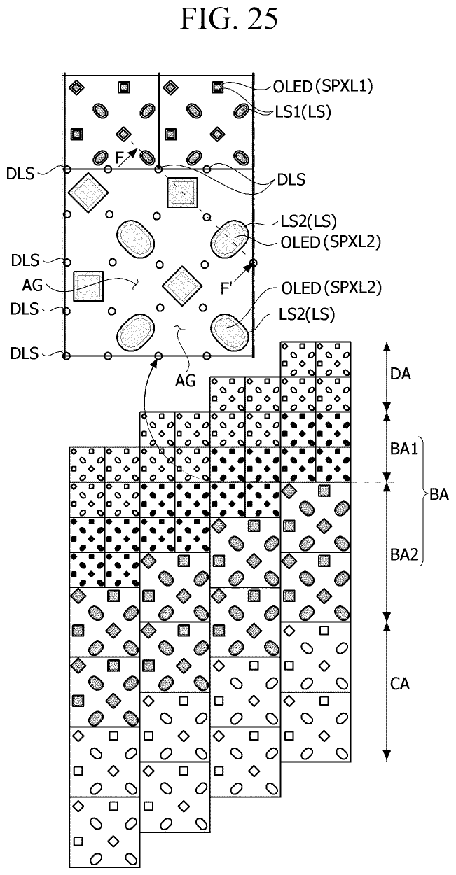

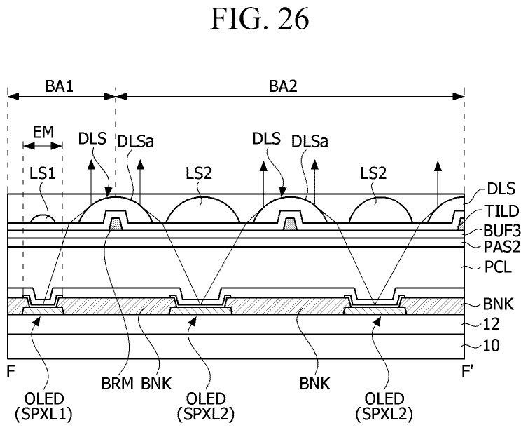

FIG. 25 is a view illustrating another embodiment of a dummy lens part arranged in the display device according to one or more embodiments of the present disclosure. For example, FIG. 25 is a plan view of a portion of a display panel according to an ninth embodiment, which can show dummy lens parts DLS located at the boundary between a first boundary area BA1 and a second boundary area BA2 and in the second boundary area BA2. FIG. 26 is a view schematically illustrating a cross-section of the boundary area of FIG. 25. FIG. 26 is a view schematically illustrating a cross-section along line F-F′ of FIG. 25. Further, the arrows shown in FIG. 26 can indicate an optical path of light emitted from the light-emitting element (OLED).

Referring to FIGS. 25 and 26, a lens part LS of the boundary area BA can include a first lens part LS1 of the first boundary area BA1 and a second lens part LS2 of the second boundary area BA2.

The first lens part LS1 can overlap the light-emitting element (OLED) of the first sub-pixel SPXL1. Further, The first lens part LS1 can be formed smaller than the emission area EM of the light-emitting element (OLED) of the first sub-pixel SPXL1, so that the luminance of the first boundary area BA1 can be lower than the luminance of the first display area DA. In this case, the size of the light-emitting element (OLED) of the first sub-pixel SPXL1 can be smaller than the size of the light-emitting element (OLED) of the second sub-pixel SPXL2, but is not necessarily limited thereto.

The second lens part LS2 can overlap the light-emitting element (OLED) of the second sub-pixel SPXL2. Further, the second lens part LS2 can be formed larger than the emission area EM of the light-emitting element (OLED) of the second sub-pixel SPXL2, so that the luminance of the second boundary area BA2 can be formed higher than the luminance in the second display area CA and lower than the luminance of the first boundary area BA1.

The first lens part LS1 and the second lens part LS2 can be different in size. For example, the size of the first lens part LS1 can be smaller than the size of the second lens part LS2. More specifically, the width of the first lens part LS1 can be smaller than the width of the second lens part LS2.

The dummy lens part DLS can overlap the bank BNK arranged between the light-emitting elements (OLED). Further, the dummy lens part DLS can be arranged on the touch interlayer insulating film TILD to overlap the bridge metal BRM of the touch sensor layer 18.

The dummy lens part DLS can be located in the second boundary area BA2. In this case, considering the number of pixels per unit area (Pixels Per Inch) of the first boundary area BA1, the spacing between the first sub-pixels SPXL1 of the first boundary area BA1, the spacing between the second sub-pixels SPXL2 of the second boundary area BA2, and the like, the dummy lens part DLS can be located in the second boundary area BA2. For example, the dummy lens part DLS can be arranged between the second lens parts LS2 arranged in the second boundary area BA2. In this case, the dummy lens part DLS can have the same size as the second lens part LS2, but is not necessarily limited thereto.

Further, the dummy lens part DLS can be located at the boundary between the first boundary area BA1 and the second boundary area BA2. Further, the size of the dummy lens part DLS located at the boundary between the first boundary area BA1 and the second boundary area BA2 can be the same as the size of the second lens part LS2, but is not necessarily limited thereto. For example, the size of the dummy lens part DLS located at the boundary between the first boundary area BA1 and the second boundary area BA2 can be the same as the size of the first lens part LS1.

Some of lights emitted from the light-emitting element (OLED) of the first boundary area BA1 and/or the second boundary area BA2 can be irradiated through the space between the first lens part LS1 and the dummy lens part DLS or the space between the second lens part LS2 and the dummy lens part DLS. In this case, lights passing through the space can be refracted by the difference in refractive index between the touch interlayer insulating layer TILD and the organic insulating layer PAC, and the refracted lights can be refracted toward the front side of the display panel 100 by the outer surface DLSa of the dummy lens part DLS. Accordingly, the luminance at the boundary between the first boundary area BA1 and the second boundary area BA2 can be improved by the dummy lens part DLS.

Thus, in the display device according to an embodiment of the present disclosure, the dummy lens part DLS located in the second boundary area BA2 can be used to improve the luminance at the second boundary area BA2. Additionally, in the display device according to the embodiment of the present disclosure, the dummy lens part DLS located at the boundary between the first boundary area BA1 and the second boundary area BA2 can be used to further improve the luminance at the boundary between the first boundary area BA1 and the second boundary area BA2. As a result, the display device according to the embodiment of the present disclosure can further prevent, reduce, or minimize visibility of the boundary due to the luminance difference between the first display area DA and the second display area CA.

The display panel according to one or more embodiments of the present disclosure and the display device including the same can be described as follows.

A display device according to one or more embodiments of the present disclosure can include a display panel including a first display area, a second display area, and a boundary area arranged between the first display area and the second display area, the first display area, the second display area and the boundary area having different luminance from each other; and a sensor corresponding to the second display area. The boundary area can include a lens part overlapping a light-emitting element.

According to one or more embodiments of the present disclosure, a luminance of the boundary area can be higher than a luminance of the second display area and lower than a luminance of the first display area.

According to one or more embodiments of the present disclosure, the display panel can include a substrate, a circuit layer arranged on the substrate, a light-emitting element layer arranged on the circuit layer and including the light-emitting element, an encapsulation layer arranged on the light-emitting element layer, and a touch sensor layer arranged on the encapsulation layer. The lens part can be arranged in the touch sensor layer.

According to one or more embodiments of the present disclosure, a spacing between a plurality of light-emitting elements arranged in the boundary area can be the same as a spacing between a plurality of light-emitting elements arranged in the second display area.

According to one or more embodiments of the present disclosure, a width of an emission area of the light-emitting element arranged in the boundary area can be smaller than a width of the lens part overlapping the light-emitting element.

According to one or more embodiments of the present disclosure, the width of the lens part can be smaller toward the second display area.

According to one or more embodiments of the present disclosure, a plurality of lens parts arranged in the boundary area can include an outer lens part adjacent to the first display area and an inner lens part adjacent to the second display area. A width of the outer lens part can be larger than a width of the inner lens part.

According to one or more embodiments of the present disclosure, the display panel can further include an middle lens part arranged between the outer lens part and the inner lens part. A width of the middle lens part can be smaller than the width of the outer lens part and larger than the width of the inner lens part.

According to one or more embodiments of the present disclosure, the boundary area can include a first boundary area including a first light-emitting element and a first lens part overlapping the first light-emitting element, and a second boundary area including a second light-emitting element and a second lens part overlapping the second light-emitting element. A first spacing between a plurality of the first light-emitting elements arranged in the first boundary area can be smaller than a second spacing between a plurality of the second light-emitting elements arranged in the second boundary area.

According to one or more embodiments of the present disclosure, a width of the first lens part can be smaller than a width of the second lens part.

According to one or more embodiments of the present disclosure, the first spacing can be equal to a spacing between a plurality of light-emitting elements arranged in the first display area. The second spacing can be equal to a spacing between a plurality of light-emitting elements arranged in the second display area.

According to one or more embodiments of the present disclosure, the width of the first lens part can be smaller than the width of an emission area of the first light-emitting element.

According to one or more embodiments of the present disclosure, the width of the second lens part can be larger than the width of an emission area of the second light-emitting element.

According to one or more embodiments of the present disclosure, the display panel can further include a dummy lens part arranged between two neighboring lens parts.

According to one or more embodiments of the present disclosure, the display panel can include a substrate, a circuit layer arranged on the substrate, a light-emitting element layer arranged on the circuit layer and including the light-emitting element, an encapsulation layer arranged on the light-emitting element layer, and a touch sensor layer arranged on the encapsulation layer. The dummy lens part can overlap a bank of the light-emitting element layer.

According to one or more embodiments of the present disclosure, the dummy lens part can arranged to be spaced apart from the lens part at predetermined interval.

According to one or more embodiments of the present disclosure, the lens part and the dummy lens part can be arranged in the touch sensor layer.

According to one or more embodiments of the present disclosure, the touch sensor layer can include a touch buffer layer arranged on the encapsulation layer, a bridge metal arranged on the touch buffer layer, and a touch interlayer insulating film covering the bridge metal. The dummy lens part can be arranged on the touch interlayer insulating film to overlap the bridge metal.

According to one or more embodiments of the present disclosure, the touch sensor layer can further include an organic insulating layer covering the lens part, the dummy lens part and the touch interlayer insulating film. A refractive index of the dummy lens part and a refractive index of the organic insulating layer can be different.

According to one or more embodiments of the present disclosure, the display panel further includes a dummy lens part, wherein the dummy lens part can overlap a bank arranged between the light-emitting element in the boundary area and a light-emitting element arranged in the first display area.

According to one or more embodiments of the present disclosure, the display panel further includes a dummy lens part, wherein the dummy lens part can overlap a bank arranged between the light-emitting element in the boundary area and a light-emitting element arranged in the second display area.

According to one or more embodiments of the present disclosure, a spacing between a plurality of light-emitting elements arranged in the boundary area can be the same as a spacing between a plurality of light-emitting elements arranged in the first display area.

According to one or more embodiments of the present disclosure, the width of an emission area of the light-emitting element arranged in the boundary area can be larger than the width of the lens part overlapping the light-emitting element.

A display device according to one or more embodiments of the present disclosure can include: a display panel including a first display area, a second display area, and a boundary area arranged between the first display area and the second display area, the first display area, the second display area and the boundary area having different luminance from each other, wherein the boundary area includes a lens part overlapping a light-emitting element, and wherein a luminance of a light emitted from the light-emitting element is adjusted by setting a size of the lens part relative to an emission area of the light-emitting element.

According to one or more embodiments of the present disclosure, the display device can further comprise a sensor corresponding to the second display area.

According to one or more embodiments of the present disclosure, the second display area can have a relatively smaller number of pixels per unit area than the first display area, and can comprise a light transmitting area arranged between a plurality of sub-pixels in the second display area.

According to one or more embodiments of the present disclosure, the boundary area can have the same number of pixels per unit area as the second display area.

According to one or more embodiments of the present disclosure, the display device can further comprise a dummy lens part arranged between two neighboring lens parts.

According to one or more embodiments of the present disclosure, the light transmitting area can be made of a transparent insulating material.

The objects to be achieved by the present disclosure, the means for achieving the objects, and effects of the present disclosure described above do not specify essential features of the claims, and thus, the scope of the claims is not limited to the disclosure of the present disclosure.

Although the embodiments of the present disclosure have been described in more detail with reference to the accompanying drawings, the present disclosure is not limited thereto and can be embodied in many different forms without departing from the technical concept of the present disclosure. Therefore, the embodiments disclosed in the present disclosure are provided for illustrative purposes only and are not intended to limit the technical concept of the present disclosure. The scope of the technical concept of the present disclosure is not limited thereto. Therefore, it should be understood that the above-described embodiments are illustrative in all aspects and do not limit the present disclosure.

### LIST OF REFERENCE NUMBERS

| | |
|---|---|
| 100: Display panel | 200: Optical device |
| 300: Drive IC | 400: Host system |
| DA: First display area | CA: Second display area |
| BA: Boundary area | BNK: Bank |
| LS: Lens part | DLS: Dummy lens part |
| OLED: Light-emitting element | PXL: Pixel |
| SPXL1: First sub-pixel | SPXL2: Second sub-pixel |

What is claimed is:

1. A display device comprising:
a display panel including a first display area, a second display area, and a boundary area arranged between the first display area and the second display area, the first display area, the second display area and the boundary area having different luminance from each other; and
a sensor corresponding to the second display area,
wherein the boundary area includes a lens part overlapping a light-emitting element.

2. The display device according to claim 1, wherein a luminance of the boundary area is higher than a luminance of the second display area and is lower than a luminance of the first display area.

3. The display device according to claim 1, wherein the display panel includes a substrate, a circuit layer arranged on the substrate, a light-emitting element layer arranged on the circuit layer and including the light-emitting element, an encapsulation layer arranged on the light-emitting element layer, and a touch sensor layer arranged on the encapsulation layer, and
wherein the lens part is arranged in the touch sensor layer.

4. The display device according to claim 1, wherein a spacing between a plurality of light-emitting elements arranged in the boundary area is the same as a spacing between a plurality of light-emitting elements arranged in the second display area.

5. The display device according to claim 1, wherein a width of an emission area of the light-emitting element arranged in the boundary area is smaller than a width of the lens part overlapping the light-emitting element.

6. The display device according to claim 5, wherein the width of the lens part is smaller toward the second display area.

7. The display device according to claim 1, wherein a plurality of lens parts arranged in the boundary area include an outer lens part adjacent to the first display area and an inner lens part adjacent to the second display area, and
wherein a width of the outer lens part is larger than a width of the inner lens part.

8. The display device according to claim 7, further comprising:
a middle lens part arranged between the outer lens part and the inner lens part,
wherein a width of the middle lens part is smaller than the width of the outer lens part and is larger than the width of the inner lens part.

9. The display device according to claim 1, wherein the boundary area includes:
a first boundary area including a first light-emitting element and a first lens part overlapping the first light-emitting element; and
a second boundary area including a second light-emitting element and a second lens part overlapping the second light-emitting element, and
wherein a first spacing between a plurality of the first light-emitting elements arranged in the first boundary area is smaller than a second spacing between a plurality of the second light-emitting elements arranged in the second boundary area.

10. The display device according to claim 9, wherein a width of the first lens part is smaller than a width of the second lens part.

11. The display device according to claim 10, wherein the first spacing is equal to a spacing between a plurality of light-emitting elements arranged in the first display area, and
wherein the second spacing is equal to a spacing between a plurality of light-emitting elements arranged in the second display area.

12. The display device according to claim 11, wherein the width of the first lens part is smaller than the width of an emission area of the first light-emitting element, and
wherein the width of the second lens part is larger than the width of an emission area of the second light-emitting element.

13. The display device according to claim 1, further comprising:
a dummy lens part arranged between two neighboring lens parts.

14. The display device according to claim 13, wherein the display panel includes a substrate, a circuit layer arranged on the substrate, a light-emitting element layer arranged on the circuit layer and including the light-emitting element, an encapsulation layer arranged on the light-emitting element layer, and a touch sensor layer arranged on the encapsulation layer, and
wherein the dummy lens part overlaps a bank of the light-emitting element layer.

15. The display device according to claim 14, wherein the dummy lens part is arranged to be spaced apart from the lens part at a predetermined interval.

16. The display device according to claim 14, wherein the lens part and the dummy lens part are arranged in the touch sensor layer.

17. The display device according to claim 16, wherein the touch sensor layer includes a touch buffer layer arranged on the encapsulation layer, a bridge metal arranged on the touch buffer layer, and a touch interlayer insulating film covering the bridge metal, and
wherein the dummy lens part is arranged on the touch interlayer insulating film to overlap the bridge metal.

18. The display device according to claim 17, wherein the touch sensor layer further includes an organic insulating layer covering the lens part, the dummy lens part and the touch interlayer insulating film, and
wherein a refractive index of the dummy lens part and a refractive index of the organic insulating layer are different from each other.

19. The display device according to claim 1, wherein the display panel further includes a dummy lens part, and
wherein the dummy lens part overlaps a bank arranged between the light-emitting element in the boundary area and a light-emitting element arranged in the first display area, or overlaps a bank arranged between the light-emitting element in the boundary area and a light-emitting element arranged in the second display area.

20. A display device comprising:
a display panel including a first display area, a second display area, and a boundary area arranged between the first display area and the second display area,
wherein the first display area, the second display area and the boundary area have different luminance from each other,
wherein the boundary area includes a lens part overlapping a light-emitting element, and
wherein a luminance of a light emitted from the light-emitting element is adjusted by setting a size of the lens part relative to an emission area of the light-emitting element.
